(19) United States
(12) Patent Application Publication
(10) Pub. No.: US 2007/0009001 A1
(43) Pub. Date: Jan. 11, 2007

(54) Semiconductor laser device

(75) Inventors: Kimio Shigihara, Tokyo (JP); Yoshihiko Hanamaki, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 11/396,771

(22) Filed: Apr. 4, 2006

(30) Foreign Application Priority Data
Jul. 11, 2005 (JP) 2005-201950
Nov. 21, 2005 (JP) 2005-336098

(51) Int. Cl. H01S 5/00

(52) U.S. Cl. 372/45.012

(57) ABSTRACT

A semiconductor laser device includes: on an n-GaAs substrate, an n-type cladding layer of n-(Al_{0.3}Ga_{0.7})_{0.5}In_{1.5}P, an n-side guide layer of i-In_{0.49}Ga_{0.51}P lattice-matched to GaAs, an active layer having a larger refractive index than the n-side guide layer, and including an In_{0.07}Ga_{0.93}As quantum well layer, a p-side guide layer of i-In_{0.49}Ga_{0.51}P, and a p-type cladding layer of p-(Al_{0.3}Ga_{0.7})_{0.5}In_{0.5}P. Therefore, the anti-COD level increased, and internal loss minimized.

### BACKGROUND OF THE INVENTION

1. Field of the Invention

The present invention relates generally to semiconductor laser devices, and more particularly, to a high-output power semiconductor laser device used as an pumping light source in an industrial laser, and to improving various semiconductor laser devices in efficiency and in reliability.

2. Description of the related Art

The semiconductor laser devices used as pumping light sources in a solid-state laser such as an Yb-doped YAG laser for use in industrial lasers, for example, in metal-machining applications, an Yb-doped fiber laser, and an Er-doped fiber amplifier, or the like, have an emission wavelength of about 940 nm and are required to ensure high-output power normal operation at this emission wavelength.

Also, conventional semiconductor laser devices with an emission wavelength of 0.8 μm have adopted a structure with an active layer sandwiched between guide layers smaller than this active layer in refractive index and greater than the active layer in bandgap energy, each of these guide layers further being sandwiched between cladding layers smaller than each guide layer in refractive index and greater than the guide layer in bandgap energy. In this structure, electrons and holes are confined in the active layer and light is confined in the guide layers, so the structure is what is called the separate-confinement heterostructure (SCH).

In a known example of a conventional semiconductor laser device with an emission wavelength of about 940 nm, n-type Al_{0.7}Ga _{0.3}Ga_{0.3}As is used as an n-type cladding layer (hereinafter, materials with electroconductivity of the “n” type is expressed as “n-” in coded representation of materials characteristics, materials with “p-type” electroconductivity, as “p-”, and materials not doped with impurities, namely, undoped materials as “i-”), Al_{0.35}Ga_{0.65}As as an n-side guide layer, GaAsP as a barrier layer, InGaAs as an active layer, Al_{0.35}Ga_{0.65}As as a p-side guide layer, and p-Al_{0.7}Ga _{0.3}Ga_{0.3}As as a p-type cladding layer. This conventional example have been described in “100 W-output power from passively cooled laser bar with 30% filling factor,” A. Knigge et al., Conference Digest of 2004 IEEE 19th International Semiconductor Laser Conference, Kunibiki Messe, Matsue-shi, Simane Pref., JAPAN, ThAl, pp. 35-36, September 2004, for example.

Also, known examples of a semiconductor laser with an emission wavelength of 650 nm include an example in which an n-AlGaInAsP cladding layer, an n-side undoped GaInP optical waveguide layer, an undoped GaInAsP active layer, a p-side undoped GaInP optical waveguide layer, and a p-AlGaInAsP cladding layer are stacked in order and a GaInP window layer is formed at a section equivalent to a cavity facet. In another such known example, an n-AlGaInAsP cladding layer, an n-side undoped GaInP optical waveguide layer, a multiple-quantum-well structure consisting of a GaInAsP active layer and a GaInP barrier layer, a p-side undoped GaInP optical waveguide layer, and a p-AlGaInAsP cladding layer are stacked in order and crystal mixing by zinc (Zn) diffusion is conducted to form a window layer at a multiple-quantum-well structural section equivalent to a cavity facet. Facts such as the ones that the absorption of light at facets is reduced for improved COD (Catastrophic Optical Damage) levels by the window layers in these examples and that because of no aluminum (Al) being contained in the respective materials, these window layers do not absorb light of levels such as a deep level in the crystal materials, and are not affected by non-radiative recombination currents, have been described in Japanese Patent Laid-Open No. 2002-134834, for example.

In addition, two examples of constructing a semiconductor laser having the GRIN SCH (graded-index separate-confinement heterostructure) that is one kind of SCH and continuously changes the refractive indices of optical guide layers have been disclosed in “0.98-μm Strained Quantum Well Lasers for Coupling High Optical Power into Single-Mode Fiber,” M. Wada et al., IEEE TRANSACTIONS PHOTONICS TECHNOLOGY LETTERS, VOL. 3, NO. 11, NOVEMBER 1991, for example. In one of the two examples of construction, an In_{0.21}Ga_{0.79}As active layer with a thickness of 0.011 μm, and non-AlₓGa₁₋ₓAs layers each of a 0.17-μm layer thickness and each with an Al-content ratio “x” continuously changing in the range from 0.5 to 0.0 are formed such that the In_{0.21}Ga_{0.79}As active layer is sandwiched between the non-AlₓGa₁₋ₓAs layers. In the other example of construction, an In_{0.21}Ga_{0.79}As active layer of a 0.011-μm layer thickness and non-AlₓGa₁₋ₓAs layers each of a 0.06-μm thickness and each with an Al-content ratio “x” continuously changing in the range from 0.4 to 0.0 are formed such that the In_{0.21}Ga_{0.79}As active layer is sandwiched between the non-AlₓGa₁₋ₓAs layers.

Furthermore, an example of constructing a semiconductor device having the GRIN SCH that changes optical guide layers stepwise is disclosed in “980-nm Aluminum-Free InGaAs/InGaAsP/InGaP GRIN-SCH SL-QW Lasers,” M. Ohkubo et al., IEEE JOURNAL OF QUANTUM ELECTRONICS, VOL. 30, NO. 2, FEBRUARY 1994, for example. In this example, a 9-nm-thick In_{0.2}Ga_{0.8}As quantum well active layer and the optical guide layers each with a bandgap energy value changing to 1.42 eV, 1.58 eV, 1.65 eV, and 1.77 eV stepwise and each with a layer thickness of 20 nm are formed such that the In_{0.2}Ga_{0.8}As quantum well active layer is sandwiched between the optical guide layers.

Besides, in “High-Efficiency AlGaAs-Based Laser Diode at 808 nm with Large Transverse Spot Size,” M. A. Emanuel et al., IEEE PHOTONICS TECHNOLOGY LETTERS, VOL. 8, NO. 10, OCTOBER 1996, for example, it has been disclosed that a semiconductor laser of an LS (large-spot) quantum well laser structure equipped with a multiple-quantum-well structure formed up of 70-Å-thick Al_{0.15}In_{0.10}Ga_{0.75}As active layers, and with AlₓGa₁₋ₓAs (x is changing linearly in the range from 0.3 to 0.2) GRIN layers formed so as to sandwich the active layers of a 0.8-μm layer thickness.

In the semiconductor laser device of a 940-nm emission wavelength, disclosed in above A. Knigge et al., since AlGaAs layers with an Al-content ratio of 0.35 are used as the guide layers, and AlGaAs layers with an Al-content ratio of 0.70, as the cladding layers, the guide layers include the regions accounting for a large portion of optical intensity distribution. Since Al-containing layers easily oxidize, there has been the problem that if a great amount of light exists in the Al-containing layers, the light is prone to cause COD and in some cases, lowers reliability.

In the semiconductor laser of a 650-nm emission wavelength, disclosed in Japanese Patent Laid-Open No. 2002-134834, AlGaInAsP layers are used as the n-type and p-type cladding layers, Al-free GaInP layers are used as the n-side and p-side optical waveguide layers, and a GaInP window layer is disposed or a window layer by crystal mixing based on Zn diffusion is disposed in the multiple-quantum-well structure consisting of a GaInAsP active layer and a GaInP barrier layer. An anti-COD level is enhanced in this way.

In order for a semiconductor laser device to operate at its high output power, however, it is important to ensure the reliability of the semiconductor laser device by enhancing the anti-COD level at the emitting facet of the laser. To achieve high-output power operation, it is also absolutely necessary to minimize any internal loss.

In SCH, since carriers stay only on active layers, quasi-Fermi levels tend to increase, which, in turn, has even increased an operating voltage in some cases. In addition, SCH has had the tendency that thickening guide layers for minimum optical loss spreads the optical intensity distribution too much, reducing the optical confinement ratios within the active layers, and thus, as the case may be, increasing a threshold current.

### SUMMARY OF THE INVENTION

The present invention was made in order to solve the above problems, and a first object of the invention is to construct a semiconductor laser device of an emission wavelengths of about 940 nm operating with highly efficiency and high reliability at a small operating current by enhancing the anti-COD level and minimizing an internal loss. A second object of the invention is to construct a semiconductor laser device of a low operating voltage and a small threshold current.

According to one aspect of the invention, there is provided a semiconductor laser device according to the present invention comprises: a first electroconductive type of GaAs substrate; a first electroconductive type of first cladding layer of (Alₓ₁Ga₁₋ₓ₁)_{y1}In_{1-y1}P (1>x1>0, 0.52>y1>0.48), disposed on the GaAs substrate; a first optical waveguide layer of undoped InᵤGa₁₋ᵤP (1>u>0) lattice-matched to GaAs, disposed on the first cladding layer; an active layer disposed on the first optical waveguide layer, the active layer being of a greater refractive index than the first optical waveguide layer and including a layer of InᵥGa₁₋ᵥAs (0.24>v>0) as a quantum-well layer; a second optical waveguide layer of undoped InᵤGa₁₋ᵤP (1>u>0), disposed on the active layer, the second optical waveguide layer being of a smaller refractive index than the active layer; and a second electroconductive type of second cladding layer of (Alₓ₂Ga₁₋ₓ₂)_{y2}In_{1-y2}P (1>x2>0, 0.52>y2>0.48), disposed on the second optical waveguide layer.

Accordingly, in the semiconductor laser device according to the present invention, laser light with emission wavelengths inclusive of about 940 nm is emitted and differences in refractive index between a first electroconductive type of first cladding layer and a first optical waveguide layer and between a second electroconductive type of second cladding layer and a second optical waveguide layer cause a majority of optical intensity distribution regions of the laser light to be confined between the first optical waveguide layer and second optical waveguide layers that are essentially free of Al. Therefore, COD that is prone to be caused by oxidization of Al is reduced, so anti-COD level becomes higher.

In addition, internal loss can be minimized since a majority of optical intensity distribution regions of the laser light are confined between the first optical waveguide layer and second optical waveguide layers that are undoped regions. Hence, it is possible to minimize internal loss and even to construct a semiconductor laser device that operates at a small current and is high in efficiency and in reliability.

According to another aspect of the invention, there is provided a semiconductor laser device according to the present invention comprises: a first electroconductive type of semiconductor substrate; a first electroconductive type of first cladding layer disposed on the semiconductor substrate; a first optical waveguide layer disposed on the first cladding layer; an active layer of a quantum well structure, disposed on the first optical waveguide layer, the active layer being of a greater refractive index than the first optical waveguide layer; a second optical waveguide layer disposed on the active layer, the second optical waveguide layer being of a smaller refractive index than the active layer; a first semiconductor layer disposed in contact with the active layer between the second optical waveguide layer or the first optical waveguide layer and the active layer, the first semiconductor layer having a bandgap energy level which is somewhere in between a bandgap energy level of the active layer and a bandgap energy level of the adjacent second optical waveguide layer or first optical waveguide layer, and which is discretely different from the bandgap energy level of the active layer and the bandgap energy level of the adjacent second optical waveguide layer or first optical waveguide layer, having a refractive index which is somewhere in between a refractive index of the active layer and a refractive index of the adjacent second optical waveguide layer or first optical waveguide layer, and being smaller than the active layer in thickness; and a second electroconductive type of second cladding layer disposed on the second optical waveguide layer; wherein a zeroth-order quantum level is in a conduction band offset or valence band offset between the active layer and the second optical waveguide layer or the first optical waveguide layer.

Accordingly, in the semiconductor laser device according to the present invention, threshold carrier density reduces, and a quasi-Fermi level of the conduction band or the valance band drops. Therefore, threshold current and operating voltage are reduced to suppress an overflow of carriers, and hence improves in high-temperature characteristics. These facts, in turn, mean that a semiconductor laser device of a low operating voltage and a small threshold current can be constructed.

Other objects and advantages of the invention will become apparent from the detailed description given hereinafter. It should be understood, however, that the detailed description and specific embodiments are given by way of illustration only since various changes and modifications within the scope of the invention will become apparent to those skilled in the art from this detailed description.

### BRIEF DESCRIPTION OF THE DRAWINGS

FIG. 1 is a perspective view of a semiconductor laser device according to one embodiment of the present invention. In the figures that follow, the same reference number indicates the same constituent element or equivalent.

FIG. 2 is a band diagram that shows vicinity of the active layer in the semiconductor laser according to one embodiment of the present invention.

FIG. 3 is another band diagram that shows vicinity of the active layer in the semiconductor laser according to one embodiment of the present invention.

FIG. 4 is a graph showing optical intensity rates in undoped regions of the semiconductor laser according to one embodiment of the present invention, versus the thicknesses of the guide layers in the laser.

FIG. 5 is a graph showing a threshold carrier density in the semiconductor laser according to the first embodiment of the present invention, versus a quantum well thickness of the laser.

FIG. 6 is a graph that shows optical output power-current characteristics of a first experimental sample of a semiconductor laser according to the first embodiment of the present invention.

FIG. 7 is a graph that shows optical output power-current characteristics of a second experimental sample of a semiconductor laser according to one embodiment of the present invention.

FIG. 8 is a perspective view of a first variation of the semiconductor laser according to one embodiment of the present invention.

FIG. 9 is a perspective view of a second variation of the semiconductor laser according to one embodiment of the present invention.

FIG. 10 is a perspective view of a third variation of the semiconductor laser according to the first embodiment of the present invention.

FIG. 11 is a perspective view of a semiconductor laser according to one embodiment of the present invention.

FIG. 12 is a graph showing optical intensity rates in undoped regions of the semiconductor laser according to one embodiment of the present invention, versus thicknesses of the guide layers in the laser.

FIG. 13 is a graph showing a threshold carrier density in the semiconductor laser according to one embodiment of the present invention, versus a quantum well thickness of the laser.

FIG. 14 is a graph showing a threshold carrier density in the semiconductor laser according to one embodiment of the present invention, versus a quantum well thickness of the laser.

FIG. 15 is a graph that shows optical output power—current characteristics of an experimental sample of a semiconductor laser according to one embodiment of the present invention.

FIG. 16 is a graph that shows optical output power—current characteristics of another experimental sample of a semiconductor laser according to one embodiment of the present invention.

FIG. 17 is a perspective view of a variation of the semiconductor laser according to one embodiment of the present invention.

FIG. 18 is a perspective view of a variation of the semiconductor laser according to one embodiment of the present invention.

FIG. 19 is a perspective view of a variation of the semiconductor laser according to one embodiment of the present invention.

FIG. 20 is a perspective view of a semiconductor laser according to one embodiment of the present invention.

FIG. 21 is a graph showing optical intensity rates in undoped regions of the semiconductor laser according to one embodiment of the present invention, versus thicknesses of the guide layers in the laser.

FIG. 22 is a graph showing a threshold carrier density in the semiconductor laser according to one embodiment of the present invention, versus a quantum well thickness of the laser.

FIG. 23 is a perspective view of a variation of the semiconductor laser according to one embodiment of the present invention.

FIG. 24 is a perspective view of a variation of the semiconductor laser according to one embodiment of the present invention.

FIG. 25 is a perspective view of a variation of the semiconductor laser according to one embodiment of the present invention.

FIG. 26 is a perspective view of another semiconductor laser according to one embodiment of the present invention.

FIG. 27 is a graph showing optical intensity rates in undoped regions of the above semiconductor laser according to one embodiment of the present invention, versus thicknesses of the guide layers in the laser.

FIG. 28 is a graph showing a threshold carrier density in the foregoing semiconductor laser according to one embodiment of the present invention, versus a quantum well thickness of the laser.

FIG. 29 is a perspective view of a variation of the semiconductor laser according to one embodiment of the present invention.

FIG. 30 is a perspective view of a variation of the semiconductor laser according to one embodiment of the present invention.

FIG. 31 is a perspective view of a variation of the semiconductor laser according to one embodiment of the present invention.

FIG. 32 is a sectional view of a semiconductor laser according to one embodiment of the present invention.

FIG. 33 is a schematic diagram showing a conduction band structure in neighborhood of the active layer in the semiconductor laser according to one embodiment of the present invention.

FIG. 34 is a graph showing the dependence of threshold carrier density on the thicknesses of the enhanced layers in the semiconductor laser according to one embodiment of the present invention.

FIG. 35 is a graph that shows dependence of the quasi-Fermi level's position coefficient “x” upon the thicknesses of the enhanced layers in the semiconductor laser according to one embodiment of the present invention.

FIG. 36 is another graph that shows the dependence of the threshold carrier density upon the thicknesses of the enhanced layers in the semiconductor laser according to one embodiment of the present invention.

FIG. 37 is another graph that shows the dependence of the quasi-Fermi level's position coefficient “x” upon the thicknesses of the enhanced layers in the semiconductor laser according to one embodiment of the present invention.

FIG. 38 is a schematic diagram showing a band structure in the neighborhood of the active layer in the semiconductor laser according to one embodiment of the present invention.

FIG. 39 is a sectional view of a variation of the semiconductor laser according to one embodiment of the present invention.

FIG. 40 is a schematic diagram showing a structure of a conduction band in neighborhood of active layers in the semiconductor laser of FIG. 39.

FIG. 41 is a sectional view of a variation of the semiconductor laser according to one embodiment of the present invention.

FIG. 42 is a schematic diagram showing a structure of a conduction band in neighborhood of an active layer in the semiconductor laser of FIG. 41.

FIG. 43 is a sectional view of a variation of the semiconductor laser according to one embodiment of the present invention.

FIG. 44 is a schematic diagram showing a structure of a conduction band in neighborhood of an active layer in the semiconductor laser of FIG. 43.

FIG. 45 is a sectional view of a variation of the semiconductor laser according to one embodiment of the present invention.

FIG. 46 is a schematic diagram showing a structure of a conduction band in neighborhood of active layers in the semiconductor laser of FIG. 45.

FIG. 47 is a sectional view of a variation of the semiconductor laser according to one embodiment of the present invention.

FIG. 48 is a schematic diagram showing a structure of a conduction band in neighborhood of active layers in the semiconductor laser of FIG. 47.

FIG. 49 is a sectional view of a variation of the semiconductor laser according to one embodiment of the present invention.

FIG. 50 is a schematic diagram showing a structure of a conduction band in neighborhood of active layers in the semiconductor laser of FIG. 49.

FIG. 51 is a sectional view of a variation of the semiconductor laser according to one embodiment of the present invention.

FIG. 52 is a schematic diagram showing a structure of a conduction band in neighborhood of active layers in the semiconductor laser of FIG. 51.

In all figures, the substantially same elements are given the same reference numbers.

### DESCRIPTION OF THE PREFERRED EMBODIMENTS

### First Embodiment

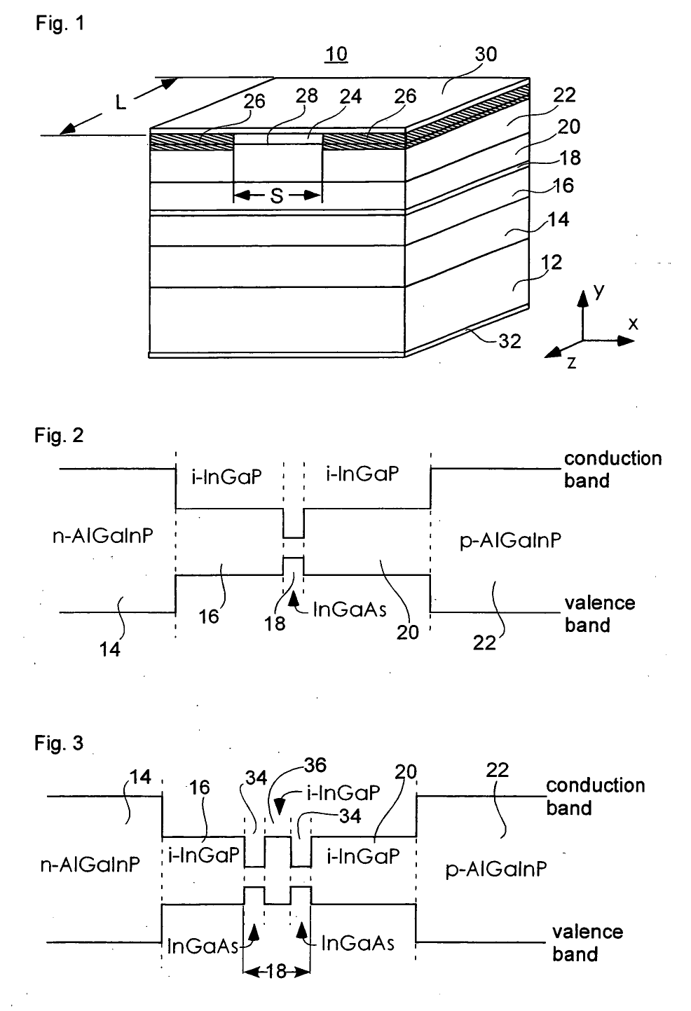

FIG. 1 is a perspective view of a semiconductor laser device according to one embodiment of the present invention. In the figures that follow, the same reference number indicates the same constituent element or equivalent.

In FIG. 1, a semiconductor laser 10 has emission wavelengths of a 940-nm band and is used as an pumping light source in solid-state laser of Yb-doped YAG laser, or others, or in Yb-doped fiber laser, Er-doped fiber amplifier, or other applications.

The semiconductor laser 10 includes the following layers each disposed in order on an n-GaAs substrate 12: an n-type cladding layer 14 as a first cladding layer, an n-side guide layer 16 as a first optical waveguide layer, an active layer 18 of a quantum well structure, a p-side guide layer 20 as a second optical waveguide layer, a p-type cladding layer 22 as a second cladding layer, and a contact layer 24 formed of p-GaAs.

At a connection section consist of the contact layer 24 and a layer which forms part of the side of the p-type cladding layer 22 that comes into contact with the contact layer 24, protons are injected into both sides of the connection section, except for a stripe region formed centrally in an x-direction of the connection section. Proton-injected regions 26 are thus provided.

Since the proton-injected regions 26 become high-resistance regions, the stripe region interposed between the proton-injected regions 26 constitutes a current path 28 on which an electric current concentrates. A stripe width of the current path 28 in an x-direction thereof is shown as S in the figure.

A p-electrode 30 formed of a gold film is provided on the surface of the contact layer 24, and an n-electrode 32 formed of a gold film, on a reverse side of the n-GaAs substrate 12.

Light is emitted from the semiconductor laser 10 in a z-direction, and both facets of the laser 10, located in the z-direction, are cleavage facets. The section between these cleavage facets is a cavity, a length of which is shown as L in the figure.

The n-GaAs substrate 12 has a layer thickness of approximately 125 μm, and a total thickness of approximately 5 μm, inclusive of respective thicknesses of the n-type cladding layer 14, the n-side guide layer 16, the active layer 18, the p-side guide layer 20, the p-type cladding layer 22, and the contact layer 24. The respective thicknesses of the n-type cladding layer 14 and the p-type cladding layer 22 are about 0.7 μm.

In the present first embodiment, although the n-type cladding layer 14 is formed of n-(Al_{0.3}Ga_{0.7})_{0.5}In_{0.5}P, an Al-content ratio x1 of the cladding layer 14 can be such a value as satisfies 1>x1>0, and the content ratio y1 of the cladding layer 14 that concerns In can be such a value as satisfies 0.52>y1>0.48.

In addition, although the n-side guide layer 16 and the p-side guide layer 20 are both formed of i-In_{0.49}Ga_{0.51}P, if both guide layers are lattice-matched to GaAs, In-content ratios of the layers can be such a value as satisfies 1>u>0.

Although the p-type cladding layer 22 is formed of p-(Al_{0.3}Ga_{0.7})_{0.5}In_{0.5}P, an Al-content ratio x2 of the cladding layer 22 can be such a value as satisfies 1>x2>0, and the content ratio y2 of the cladding layer 22 that concerns. In can be such a value as satisfies 0.52>y2>0.48.

FIG. 2 is a band diagram that shows vicinity of the active layer in the semiconductor laser according to one embodiment of the present invention.

In the semiconductor laser 10 of the present first embodiment, the active layer 18 is formed of In_{0.07}Ga_{0.93}As with an In-content ratio of 0.07 so that the semiconductor laser has a wavelength of 940 nm. However, for use as an pumping light source in Yb-doped fiber laser, Er-doped fiber amplifier, or other applications, the emission wavelength needs to be increased to, for example, 1.06 μm, so the In-content ratio can be such that it satisfies 0.24>v>0. Also, the active layer 18 of the semiconductor laser 10 is, in this case, formed into a single-quantum-well structure as an example.

FIG. 3 is another band diagram that shows vicinity of the active layer in the semiconductor laser according to one embodiment of the present invention.

In the semiconductor laser 10 of the present first embodiment, the active layer 18, although formed into a single-quantum-well structure, can be of a multiple-quantum-well structure in which, as shown in FIG. 3, a barrier layer 36 of the same material as that of the n-side guide layer 16 or the p-side guide layer 20, is disposed as an quantum well interlayer between quantum well layers 34. In addition, the number of multiple quantum wells can be more than two.

The semiconductor laser 10 applies a voltage between the p-electrode 30 and the n-electrode 32, concentrates a current through the current path 28 interposed between the proton-injected regions 26, and emits laser light in the vicinity of the active layer 18. Appropriately selecting a difference in refractive index between the n-type cladding layer 14 and the n-side guide layer 16, and a difference in refractive index between the p-type cladding layer 22 and the p-side guide layer 20, enables a great amount of generated laser light in optical intensity distributions to be distributed in the regions inclusive of the n-side guide layer 16, active layer 18, and p-side guide layer 20 which are free of Al.

Layers free of Al do not easily oxidize. Therefore, an anti-COD level of the laser can be enhanced and thus, laser reliability can be raised.

In addition, to achieve a higher output power of the semiconductor laser, it is important to reduce an internal loss of the laser. An internal loss of the semiconductor laser is caused mainly by free-carrier absorption due to dopant usage in the semiconductor layers doped with p-type or n-type impurities. That is to say, internal loss increases if a large portion of intensity distribution of the light repeatedly amplified by two-way propagation across the cavity of the semiconductor laser is present in the doped semiconductor layers. Conversely, internal loss decreases, provided that only a small portion of intensity distribution of the light repeatedly amplified is present in the doped semiconductor layers.

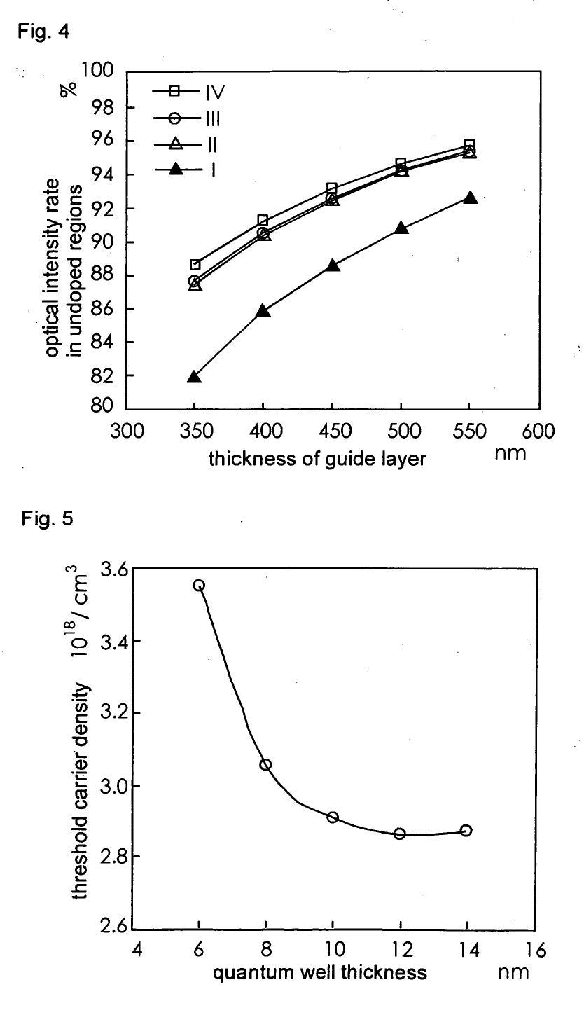

FIG. 4 is a graph showing optical intensity rates in undoped regions of the semiconductor laser according to one embodiment of the present invention, versus the thicknesses of the guide layers in the laser.

FIG. 4 assumes a configuration of the semiconductor laser 10 as a basic configuration, and calculation conditions on each of the curves shown in the figure are as described below.

That is, for the active layer including a single-quantum-well layer formed of In_{0.07}Ga_{0.93}As:

(1) Curve I (▴) applies when the n-type cladding layer 14 and the p-type cladding layer 22 have an Al-content ratio of 0.10 in AlGaInP and the active layer 18 is 6 nm thick (in the present first embodiment, equivalent to the thickness of the quantum well layer).

(2) Curve II (Δ) applies when the n-type cladding layer 14 and the p-type cladding layer 22 have an Al-content ratio of 0.15 in AlGaInP and the active layer 18 is 6 nm thick.

(3) Curve III (∘) applies when the n-type cladding layer 14 and the p-type cladding layer 22 have an Al-content ratio of 0.15 in AlGaInP and the active layer 18 is 8 nm thick.

(4) Curve IV (□) applies when the n-type cladding layer 14 and the p-type cladding layer 22 have an Al-content ratio of 0.15 in AlGaInP and the active layer 18 is 14 nm thick.

A horizontal axis in FIG. 4 indicates guide layer thickness, and this guide layer thickness is the thickness of the n-type and p-type guide layers 16 and 20, respectively, based on the assumption that both guide layers are of the same thickness.

A vertical axis indicates a optical intensity rate, which is a optical intensity distribution rate of the light included in the n-type cladding layer 14, active layer 18, and p-side guide layer 20 that are undoped regions.

As can be seen from FIG. 4, when the n-type cladding layer 14 and the p-type cladding layer 22 have an Al-content ratio of 0.10 in AlGaInP, the thickness of the active layer 18 is 6 nm or more, and the guide layer thickness is 400 nm or more, the optical intensity rate of the undoped regions is 86% or more (hereinafter, when the n-type guide layer 16 and the p-type guide layer 20 are collectively discussed, both are referred to simply as the guide layers).

When the thickness of the active layer 18 is 6 nm or more, the n-type cladding layer 14 and the p-type cladding layer 22 have an Al-content ratio of 0.15 in AlGaInP, and the guide layer thickness is 400 nm or more, the optical intensity rate of the undoped regions is in excess of 90%.

A refractive index of the AlGaInP decreases as an Al-content ratio thereof increases. When the Al-content ratios in the AlGaInP of the n-type cladding layer 14 and the p-type cladding layer 22 exceed 0.15, the differences in refractive index between the n-type guide layer 16 formed of i-In_{0.49}Ga_{0.51}P and the n-type cladding layer 14, and between p-type guide layer 20 formed of i-In_{0.49}Ga_{0.51}P and the p-type cladding layer 22, become even more significant. Accordingly, when the respective layer thicknesses of the n-type guide layer 16 and the p-type guide layer 20 are 400 nm or more, the undoped regions exceed 90% in terms of optical intensity rate.

Additionally, the refractive index of the AlGaInP decreases as the Al-content ratio increases, and the refractive indices of the AlGaInP layers containing even a slight quantity of Al will decrease below refractive indices of InGaP layers. The semiconductor laser according to the present invention is constructed so that the differences in refractive index between the dopant-free guide layers and the doped cladding layers are utilized to make the distribution of optical intensity exist in the dopant-free guide layers as much as possible. Therefore, provided that AlGaInP layers are used as the cladding layers and InGaP layers as the guide layers, even if the Al-content ratios of the AlGaInP layers are less than 0.15, thickening the guide layers enables laser light to be confined so that at least 90% of the optical intensity distribution exists in the undoped regions.

As compared curve II for the 6-nm active layer thickness with curve III for the 8-nm active layer thickness, there is almost no difference in the rates of optical intensity distribution in the undoped regions between two curves. This means that for an active layer thickness of 8 nm or less, since the active layer is thin, its refractive index little affects the rates of optical intensity distribution in the undoped regions, and hence that the optical intensity distribution in the semiconductor laser is determined primarily by the differences in refractive index between the n-type cladding layer 14 and the n-side guide layer 16 and between the p-type cladding layer 22 and the p-side guide layer 20.

According to the present inventors' own experiments, when light is confined in undoped semiconductor layers so that at least a 90% optical intensity distribution exists in the undoped regions, it becomes clear that an internal loss of the semiconductor laser is controlled below 1 cm⁻¹.

This indicates that although an internal loss of the semiconductor laser can be reduced considerably even for curve I, the internal loss can be controlled below 1 cm⁻¹ by thickening the n-side guide layer 16 and the p-side guide layer 20 to at least 400 nm for curve II, III, and IV.

Particularly for the semiconductor laser device used as an pumping light source in, for example, a solid-state laser, the semiconductor laser desirably has its internal loss controlled below 1 cm⁻¹.

Therefore, an internal loss of the semiconductor laser 10 in the present first embodiment, for example, can be controlled below 1 cm⁻¹ by constructing the laser 10 so as to have an n-type cladding layer 14 formed of n-(Al_{0.3}Ga_{0.7})_{0.5}In_{0.5}P, an n-side guide layer 16 and a p-side guide layer 20 both formed of i-In_{0.49}Ga_{0.51}P, an active layer 18 formed as a quantum well layer of In_{0.07}Ga_{0.93}As, and P-type cladding layer 22 formed of p-(Al_{0.3}Ga_{0.7})_{0.5}In_{0.5}P and so as to assign a layer thickness of at least 6 nm to the active layer 18 and a respective layer thickness of at least 400 nm to the n-side guide layer 16 and the p-side guide layer 20.

The graph of FIG. 4 that shows the optical intensity rates in the undoped regions of the semiconductor laser versus the guide layer thickness is based on the calculation method employed in the multiplex division method described in known literature, for example, P. J. B. Clarricoats and K. B. Chan, “Electromagnetic-wave propagation along radially inhomogeneous dielectric cylinders”, Electronics Letters, 29th Oct. 1970, Vol. 6, No. 22, pp. 694-695.

Next, simulation of whether the semiconductor laser 10 can emit light will be described.

FIG. 5 is a graph showing a threshold carrier density in the semiconductor laser according to the first embodiment of the present invention, versus a quantum well thickness of the laser.

That is to say, FIG. 5 shows quantum-well layer thickness dependence of the threshold carrier density required for laser light emission of the semiconductor laser.

Calculation conditions in connection with FIG. 5 assume that the semiconductor laser 10 is constructed so that both the n-side guide layer 16 and the p-side guide layer 20 are 550 nm thick. The calculation conditions also assume that the semiconductor laser has a front reflectance of 13%, a rear reflectance of 98%, a cavity length of 1000 μm, and an internal loss of 0.8 cm⁻¹.

The graph of FIG. 5 is based on the calculation method employed in the density matrix method described in known literature, for example, M. Asada, A. Kameyama, and Y. Suematsu, “Gain and intervalence band absorption in quantum-well lasers”, IEEE J. of Quantum Electronics, VOL. QE-20, NO. 7, pp. 745-753, JULY 1984.

FIG. 5 indicates that the threshold carrier density of the semiconductor laser decreases with increases in a thickness of a quantum well layer and that when the thickness of the quantum well layer is increased to about 12 nm, the threshold carrier density becomes a minimum. FIG. 5 also indicates that conversely, a further increase in the thickness of the quantum well layer increases the threshold carrier density.

This is due to the fact that whereas a greater quantum effect is obtainable in regions of quantum-well layer thicknesses less than about 12 nm, a confinement ratio of light in the active layer decreases and the threshold carrier density increases as a result.

In regions exceeding about 12 nm in quantum-well layer thickness, although the confinement ratio of light in the active layer increases, the quantum effect obtained will decrease conversely and the threshold carrier density will increase. As shown in FIG. 5, a sufficient gain necessary for laser light emission can be obtained if the thickness of the quantum well layer in a single-quantum-well structure is at least 6 nm or if a total thickness of the quantum well layers in a multiple-quantum-well structure is at least 6 nm.

Also, since the threshold carrier density is minimized in vicinity of the 12-nm quantum-well layer thickness, the threshold current becomes a minimum by formation of an active layer of a single-quantum-well structure with a layer thickness of about 12 nm, or by formation of active layers of a multiple-quantum-well structure with a total quantum-well layer thickness of about 12 nm, for example, active layers both with, for example, a 6-nm layer thickness in a double-quantum-well structure.

The gain of a semiconductor laser is determined mainly by the thickness of its active layer, the bandgap of the active layer, and the bandgaps of guide layers. In addition, facet reflectances, cavity length, and the like only affect the total loss ratio of the semiconductor laser, and the thicknesses of the guide layers in InGaP and the Al-content ratios of cladding layers in AlGaInP merely change the confinement ratio of light in the section of the active layer in terms of the optical intensity distribution of the semiconductor laser. In consideration of these factors, even if facet reflectances in the semiconductor laser 10 and/or the Al-content ratios of the cladding layers in the AlGaInP of the laser are varied, the curve shown in FIG. 5 will only shift upwards or downwards along the vertical axes.

That is to say, the above simulation results on whether the semiconductor laser 10 can properly emit laser light mean not to be limited in the case described above and that the semiconductor laser can properly operate, for example, even when the cladding layers in AlGaInP are varied in Al-content ratio.

A maximum permissible thickness of the active layer is determined by the critical film thickness shown in known literature, for example, I. J. Fritz, S. T. Picraux, L. R. Dawson, and T. J. Drummond, “Dependence of critical layer thickness on strain for InₓGa₁₋ₓAs/GaAs strained layer superlattices”, Appl. Phys. Lett. 46(10), 15 May 1985, pp. 967-969.

A maximum active layer thickness permissible for the critical film thickness of the InGaAs which is lattice-matched to GaAs is considered to range from about 30 nm to about 40 nm. If the active layer is of a single-quantum-well structure, although the maximum permissible thickness of the quantum well layer is from about 30 nm to about 40 nm, a layer thickness range in which the quantum effect works effectively is about 20 nm or less.

If the active layer is of a multiple-quantum-well structure, a total maximum permissible thickness of quantum well layers is considered to be from about 30 nm to about 40 nm.

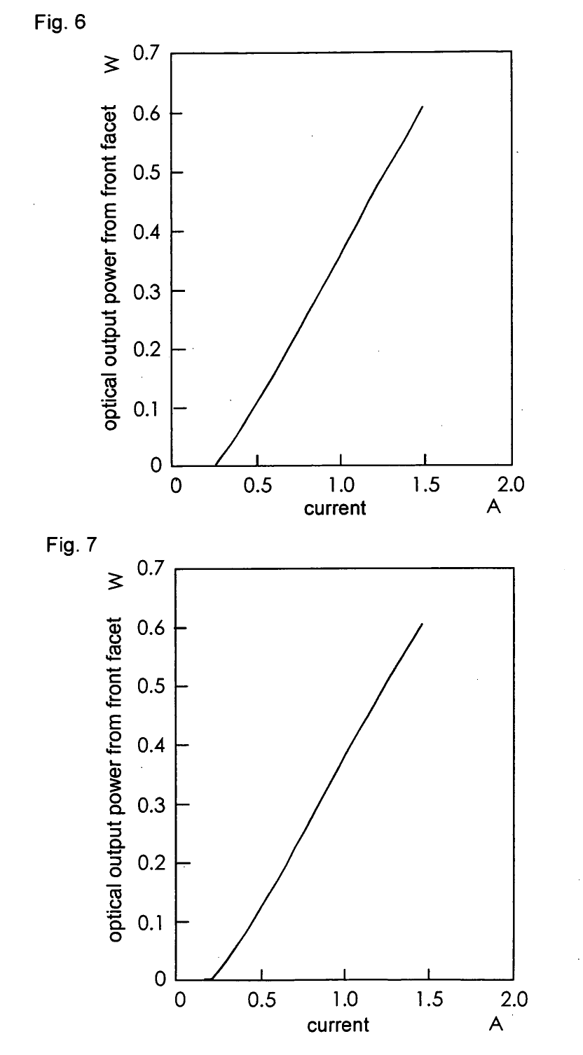

FIG. 6 is a graph that shows optical output power-current characteristics of a first experimental sample of a semiconductor laser according to the first embodiment of the present invention.

The semiconductor laser as the first experimental sample, is of the same configuration as that of the semiconductor laser 10. In this configuration, an active layer is 12 nm thick, an n-side guide layer and a p-side guide layer are both 500 nm thick, and cavity length is 1000 μm. Front and rear facets of the cavity are non-coated cleavage facets. Reflectance at the cleavage facets is about 32%. A current-conducting width, namely, the stripe width of the current path 28 interposed between the proton-injected regions 26 in the semiconductor laser 10 is 60 μm.

Only changes in an optical output power of the light emitted from the front facet are shown in FIG. 6. In consideration of an optical output power of the light emitted from the rear facet as well, total optical output power becomes twice the data shown in FIG. 6.

The semiconductor laser as the first experimental sample, exhibits favorable characteristics at a threshold current of 0.198 A, an operating current of 1.545 A for a 0.6-W output power, and a slope efficiency of 0.445 W/A. An emission wavelength at the 0.6-W output power is 940.7 nm.

FIG. 7 is a graph that shows optical output power-current characteristics of a second experimental sample of a semiconductor laser according to one embodiment of the present invention.

The semiconductor laser as the second experimental sample, is of essentially the same configuration as that of the first experimental sample, except that an n-side guide layer and a p-side guide layer are both 550 nm thick.

The semiconductor laser as the second experimental sample, exhibits favorable characteristics at a threshold current of 0.186 A, an operating current of 1.482 A for a 0.6-W output power, and a slope efficiency of 0.463 W/A. An emission wavelength at the 0.6-W output power is 943.2 nm. In the semiconductor laser as the second experimental sample, since guide layers are thicker than those of the semiconductor laser as the first experimental sample, a greater confinement ratio of light is achieved in undoped regions. Consequently, the semiconductor laser as the second experimental sample, compared with the semiconductor laser as the first experimental sample, is small in threshold current and high in slope efficiency.

First Variation

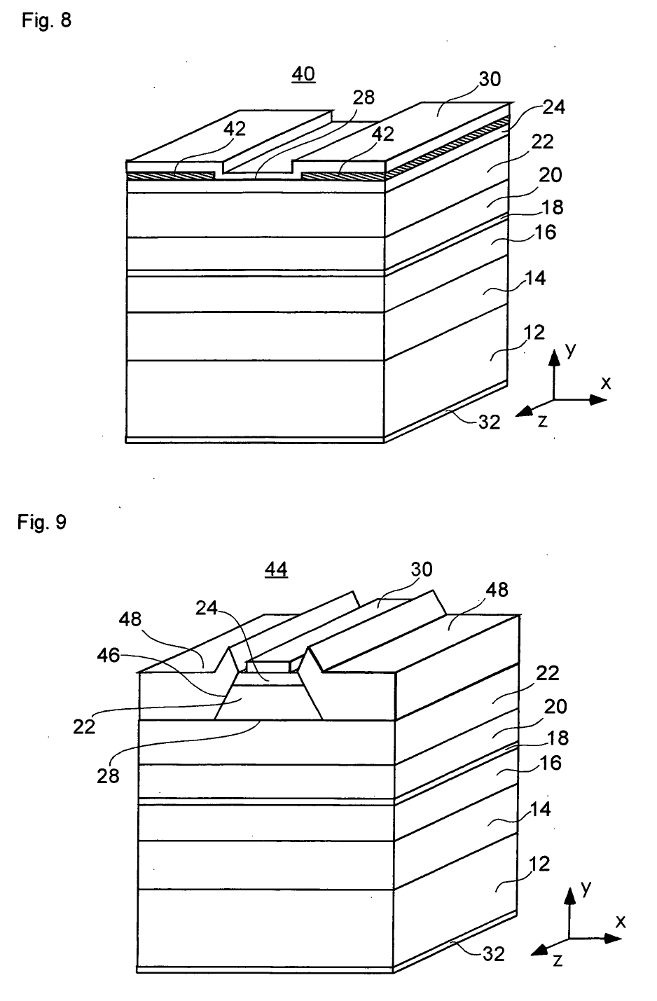

FIG. 8 is a perspective view of a first variation of the semiconductor laser according to one embodiment of the present invention.

In FIG. 8, semiconductor laser 40 is essentially the same as the semiconductor laser 10 in terms of basic configuration. However, the semiconductor laser 40 differs in current constriction structure.

In the semiconductor laser 10, at the connection section consist of the contact layer 24 and the layer forming a part of the side of the p-type cladding layer 22 that comes into contact with the contact layer 24, protons are injected into both sides of the connection section, except for the stripe region formed centrally in the x-direction of the connection section. Proton-injected regions 26 are thus provided. Also, the stripe region sandwiched between the proton-injected regions 26 is formed as a current path 28.

In the semiconductor laser 40, however, a dielectric film 42 is formed on the surfaces of both sides of a contact layer 24, except for a stripe region formed centrally in an x-direction of the contact layer 24, and the stripe region of the contact layer 24 which comes into contact with a p-electrode 30 provided on the surface of the contact layer 24 functions as a current path 28. Other structural aspects are the same as for the semiconductor laser 10.

The semiconductor laser 40 has advantageous effects in that it yields effects equivalent to those of the semiconductor laser 10, and in that since the current constriction structure can be formed using inexpensive process apparatus, the semiconductor laser 40 itself can be provided at a low price.

Second Variation

FIG. 9 is a perspective view of a second variation of the semiconductor laser according to one embodiment of the present invention.

In FIG. 9, semiconductor laser 44 is essentially the same as the semiconductor laser 10 in terms of basic configuration. However, the semiconductor laser 44 differs in current constriction structure.

The current constriction structure of the semiconductor laser 10 is as set forth in the description thereof and in the description of the first variation.

In the semiconductor laser 44, a contact layer 24 and a layer forming a part of the side of a p-type cladding layer 22 which comes into contact with the contact layer 24 form optical waveguide ridges 46 centrally in an x-direction of the cladding layer 22. A current constriction layer 48 of n-(Al_{0.4}Ga_{0.6})_{0.5}In_{0.5}P is provided on both sides externally to the optical waveguide ridges 46, and the optical waveguide ridges 46 are embedded in the respective current constriction layers 48. A p-electrode 30 is located on the surface of the contact layer 24 of the optical waveguide ridges 46. Other structural aspects are the same as for the semiconductor laser 10.

The semiconductor laser 44 has advantageous effects in that it yields effects equivalent to those of the semiconductor laser 10, and in that since the current constriction structure can be formed in a crystal growth process, wafer processing can be simplified and the semiconductor laser 44 itself can be provided at a low price.

Third Variation

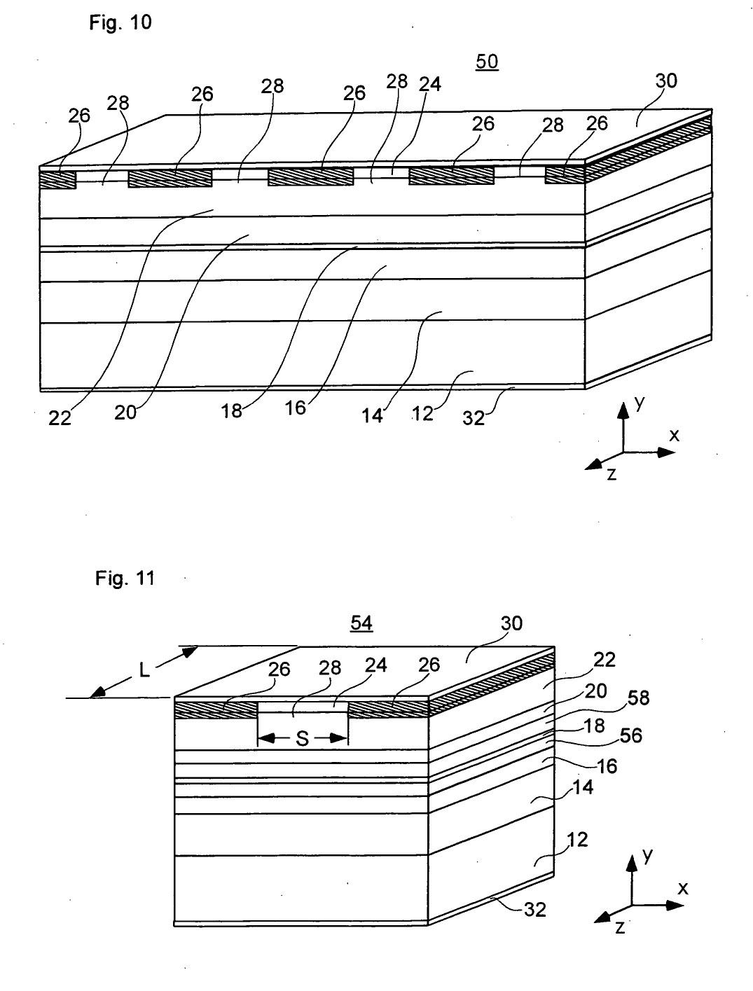

FIG. 10 is a perspective view of a third variation of the semiconductor laser according to the first embodiment of the present invention.

In FIG. 10, semiconductor laser 50 is essentially the same as the semiconductor laser 10 in terms of basic configuration. However, the semiconductor laser 50 differs from the semiconductor laser 10 in that the number of proton-injected regions is increased to form a plurality of current paths 28.

The semiconductor laser 50 is a four-piece array-type semiconductor laser, which has four current paths 28. An array-type semiconductor laser structure with even more arrays can be manufactured by extending the semiconductor laser 50 dimensionally in an x-direction thereof and further increasing the number of proton-injected regions 26. Increasing the number of arrays enables a larger-output power semiconductor laser to be constructed.

As described above, the semiconductor laser according to the present first embodiment comprises: a first electroconductive type of GaAs substrates first electroconductive type of first cladding layer of (Alₓ₁Ga₁₋ₓ₁)_{y1}, In_{1-y1}P (1>x1>0, 0.52>y1>0.48), disposed on the GaAs substrate; a first optical waveguide layer of undoped InᵤGa₁₋ᵤP (1>u>0) lattice-matched to GaAs, disposed on the first cladding layer; an active layer disposed on the first optical waveguide layer, the active layer being of a greater refractive index than the first optical waveguide layer and including a layer of InᵥGa₁₋ᵥAs (0.24>v>0) as a quantum-well layer; a second optical waveguide layer of undoped InᵤGa₁₋ᵤP (1>u>0), disposed on the active layer, the second optical waveguide layer being of a smaller refractive index than the active layer; and a second electroconductive type of second cladding layer of (Alₓ₂Ga₁₋ₓ₂)_{y2}In_{1-y2}P (1>x2>0, 0.52>y2>0.48), disposed on the second optical waveguide layer. Since the active layer has InᵥGa₁₋ᵥAs (0.24>v>0) as a quantum well layer, the semiconductor laser emits laser light of emission wavelengths inclusive of nearly 940 nm, differences in refractive index between the first electroconductive type of first cladding layer and the first optical waveguide layer and between the second electroconductive type of second cladding layer and the second optical waveguide layer cause a majority of optical intensity distribution regions of the laser light to be confined between the first optical waveguide layer and second optical waveguide layers that are essentially free of Al. Therefore, COD that is caused by oxidization of Al is reduced, so anti-COD level is enhanced. In addition, since a majority of optical intensity distribution regions of the laser light are confined between the first optical waveguide layer and second optical waveguide layers that are undoped regions, it is possible to minimize internal loss and even to construct a semiconductor laser device that operates at a small current and is high in efficiency and in reliability.

Furthermore, the active layer includes one or a plurality of quantum well layers and wherein a total layer thickness of the one or a plurality of quantum well layers is about 12 nm. Accordingly the semiconductor laser enables to be further reduced in threshold carrier density and in threshold current.

Besides, the first cladding layer and the second cladding layer both have an Al-content ratio of at least 0.1, and the first optical waveguide layer and the second optical waveguide layer both have a layer thickness of at least 400 nm. Accordingly, the optical intensity distribution of the laser light existing between the first optical waveguide layer and second optical waveguide layer that are undoped regions can be increased to at least 86%.

Further, the optical intensity distribution of the laser light existing between the first optical waveguide layer and second optical waveguide layer that are undoped regions can be further increased to at least 90% by constructing the first and second cladding layers so as to obtain an Al-content ratio of 0.15 or more and assigning a layer thickness of 400 nm or more to both the first and second optical waveguide layers.

### Second Embodiment

FIG. 11 is a perspective view of a semiconductor laser according to one embodiment of the present invention.

Semiconductor laser 54 in FIG. 11 differs from the semiconductor laser 10 of the first embodiment in that an n-side first barrier layer 56 is provided between an n-side guide layer 16 serving as a first barrier layer and an active layer 18, and in that a p-side first barrier layer 58 serving as another first barrier layer is provided between the active layer 18 and a p-side guide layer 20. Other structural aspects of the semiconductor laser 54 are the same as for the semiconductor laser 10.

The n-side first barrier layer 56 and the p-side first barrier layer 58 are both formed of i-GaAs_{0.88}P_{0.12}, an undoped semiconductor. Also, both the n-side first barrier layer 56 and the p-side first barrier layer 58 are 10 nm thick.

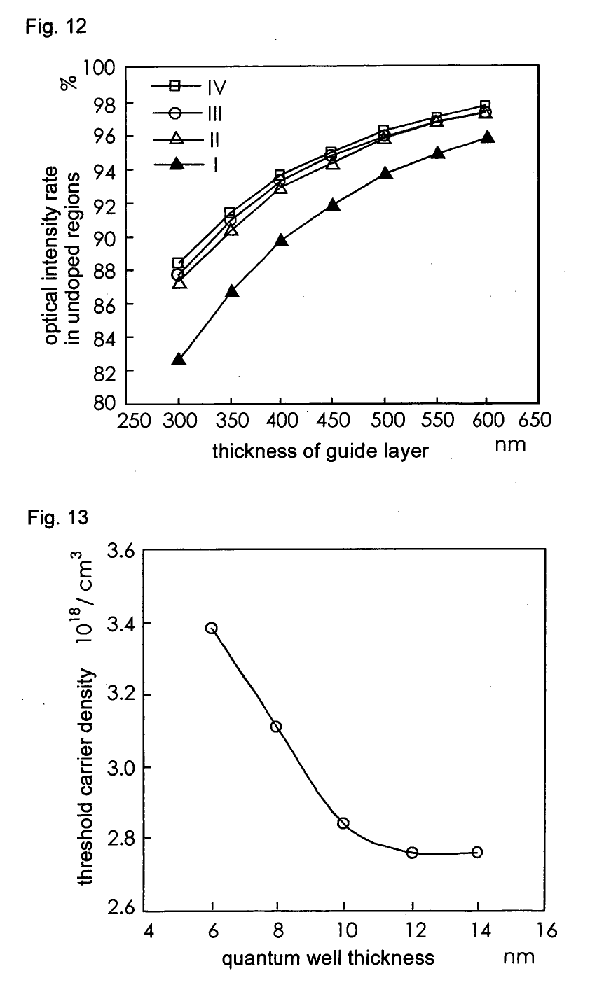

FIG. 12 is a graph showing optical intensity rates in undoped regions of the semiconductor laser according to one embodiment of the present invention, versus thicknesses of the guide layers in the laser.

FIG. 12 assumes a configuration of the semiconductor laser 54 as a basic configuration, and calculation conditions on each of the curves I (▴), II (Δ), III (∘), and IV (□) shown in the figure are the same as the conditions described in FIG. 4 of the first embodiment.

A horizontal axis in FIG. 12 indicates guide layer thickness, and this guide layer thickness is the thickness of the n-type and p-type guide layers 16 and 20, respectively, based on the assumption that both guide layers are of the same thickness. A vertical axis indicates a optical intensity rate of undoped regions, and this rate is a optical intensity distribution rate of the light included in the n-side guide layer 16, n-side first barrier layer 56, active layer 18, and p-side first barrier layer 58, and p-side guide layer 20 that are the undoped regions.

As can be seen from FIG. 12, when an n-type cladding layer 14 and a p-type cladding layer 22 have an Al-content ratio of 0.10 in AlGaInP, the thickness of the active layer 18 is 6 nm or more, and the guide layer thickness is 350 nm or more, the optical intensity rate of the undoped regions is 86% or more.

When the thickness of the active layer 18 is 6 nm or more, the n-type cladding layer 14 and the p-type cladding layer 22 have an Al-content ratio of 0.15 in AlGaInP, and the guide layer thickness is 350 nm or more, the optical intensity rate of the undoped regions is in excess of 90%.

These facts indicate that it is possible, by providing the n-side first barrier layer 56 and the p-side first barrier layer 58, to enhance a confinement ratio of light in an active-layer section of optical intensity distribution of the semiconductor laser, and hence to confine the light effectively in the undoped regions. It is possible even to effectively construct a semiconductor laser device that operates at a small current and is high in efficiency and in reliability. Additionally, changing the thickness of the active layer 18 causes essentially no change in the optical intensity rate of the undoped regions. This means that the optical intensity rate of the semiconductor laser is defined by the difference between the refractive index determined mainly by the barrier layers and the guide layers, and a refractive index of the cladding layers.

The calculation conditions in FIG. 12 assume that both the n-side first barrier layer 56 and the p-side first barrier layer 58 are 10 nm thick.

The first barrier layers (hereinafter, when the n-side first barrier layer 56 and the p-side first barrier layer 58 are collectively discussed, both are referred to simply as the first barrier layers) affect the optical intensity distribution in the undoped regions of the semiconductor laser in terms of the effective refractive index defined by the refractive indices and layer thicknesses of these first barrier layers. Increasing the thicknesses of the first barrier layers also increases the effective refractive index. When the respective thicknesses of the first barrier layers exceed 10 nm, therefore, assigning a guide layer thickness of at least 350 nm for a layer thickness of at least 6 nm of the active layer 18 and an Al-content ratio of 0.15 of the n-type cladding layer 14 and p-type cladding layer 22 in AlGaInP naturally makes the optical intensity rate in the undoped regions exceed 90%.

Also, even when the respective thicknesses of the first barrier layers are less than 10 nm, the optical intensity rate in the undoped regions can be increased above 90% at the guide layer thickness of at least 350 nm by raising the Al-content ratio of the n-type cladding layer 14 and p-type cladding layer 22 in AlGaInP to a value greater than 0.15. The reason for the increase is that as the Al-content ratio in AlGaInP increases, the refractive index thereof decreases.

For example, the curves II, III, and IV in FIG. 12 apply when an Al-content ratio of 0.15 is assigned as an example. Assigning an Al-content ratio greater than 0.15, however, produces greater differences in refractive index between the n-type cladding layer 14 and the n-side guide layer 16 and between the p-side guide layer 20 and the p-type cladding layer 22. Even when the respective thicknesses of the first barrier layers are less than 10 nm, therefore, the optical intensity rate in the undoped regions can be increased above 90% at the guide layer thickness of at least 350 nm.

Providing the n-side first barrier layer 56 and the p-side first barrier layer 58 in this way makes it possible to enhance the effective refractive index defined by the n-side first barrier layer 56, the p-side first barrier layer 58, the n-side guide layer 16, and the p-side guide layer 20. Consequently, it becomes possible to raise the flexibility of the semiconductor laser configuration that enhances the optical intensity rate in the undoped regions, and hence to easily construct a semiconductor laser device that operates at a small current and is high in efficiency and in reliability.

FIG. 13 is a graph showing a threshold carrier density in the semiconductor laser according to one embodiment of the present invention, versus a quantum well thickness of the laser.

That is to say, FIG. 13 shows quantum-well layer thickness dependence of the threshold carrier density required for laser light emission of the semiconductor laser.

The calculation conditions in connection with FIG. 13 assume that the semiconductor laser 54 is constructed so that both the n-side guide layer 16 and the p-side guide layer 20 are 600 nm thick as an example. The calculation conditions also assume that the semiconductor laser has a front reflectance of 13%, a rear reflectance of 98%, a cavity length of 1000 μm, and an internal loss of 0.8 cm⁻¹.

As shown in FIG. 13, similarly to the first embodiment, a sufficient gain necessary for laser light emission can be obtained if the total thickness of the quantum well layer is at least 6 nm.

Also, similarly to the first embodiment, since the threshold carrier density is minimized in vicinity of a 12-nm quantum-well layer thickness, the threshold current becomes a minimum by formation of an active layer of a single-quantum-well structure with a layer thickness of about 12 nm, or by formation of active layers of a multiple-quantum-well structure with a total quantum-well layer thickness of about 12 nm. The reason for that is the same as the reason set forth in the first embodiment.

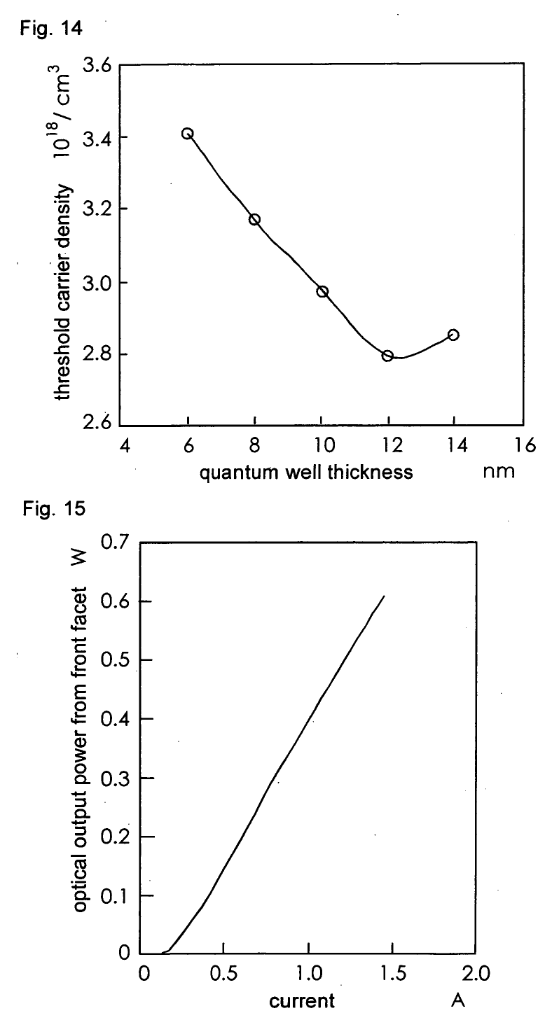

FIG. 14 is a graph showing a threshold carrier density in the semiconductor laser according to one embodiment of the present invention, versus a quantum well thickness of the laser.

Calculation conditions in connection with FIG. 14 assume that although this semiconductor laser has the same configuration as that of the semiconductor laser 54, i-GaAs_{0.9}P_{0.1} with a P-content ratio of 0.1 in GaAsP is used as an example to form the n-side first barrier layer 56 and the p-side first barrier layer 58, and both the n-side first barrier layer 56 and the p-side first barrier layer 58 are 8 nm thick. Other calculation conditions are the same as for FIG. 13. That is, both the n-side guide layer 16 and the p-side guide layer 20 are 600 nm thick. Also, the semiconductor laser has a front reflectance of 13%, a rear reflectance of 98%, a cavity length of 1000 μm, and an internal loss of 0.8 cm⁻¹.

In FIG. 14, as in FIG. 13, a sufficient gain necessary for laser light emission can be obtained if the total thickness of the quantum well layer is at least 6 nm. Also, since the threshold carrier density is minimized in vicinity of a 12-nm quantum-well layer thickness, the threshold current becomes a minimum by formation of an active layer(s) of a single- or multiple-quantum-well structure with a total layer thickness of about 12 nm.

FIG. 15 is a graph that shows optical output power—current characteristics of an experimental sample of a semiconductor laser according to one embodiment of the present invention.

The semiconductor laser as this third experimental sample, is of the same configuration as that of the semiconductor laser 54. That is, an active layer is 12 nm thick, an n-side guide layer and a p-side guide layer are both 550 nm thick, and cavity length is 1000 μm. An n-side first barrier layer 56 and a p-side first barrier layer 58 are formed of i-GaAs_{0.88}P_{0.12} whose p-content ratio in GaAsP is 0.12. Both the n-side first barrier layer 56 and the p-side first barrier layer 58 are 10 nm thick. Front and rear facets of the cavity are non-coated cleavage facets. Both reflectance at the cleavage facets are about 32%. A current-conducting width, namely, a stripe width of a current path 28 interposed between proton-injected regions 26 in the present semiconductor laser 10 is 60 μm.

Only changes in an optical output power of the light emitted from the front facet are shown in FIG. 15. In consideration of an optical output power of the light emitted from the rear facet as well, total optical output power becomes twice the data shown in FIG. 15. The semiconductor laser as the third experimental sample, exhibits favorable characteristics at a threshold current of 0.131 A, an operating current of 1.419 A for a 0.6-W output power, and a slope efficiency of 0.466 W/A. An emission wavelength at the 0.6-W output power is 946.6 nm.

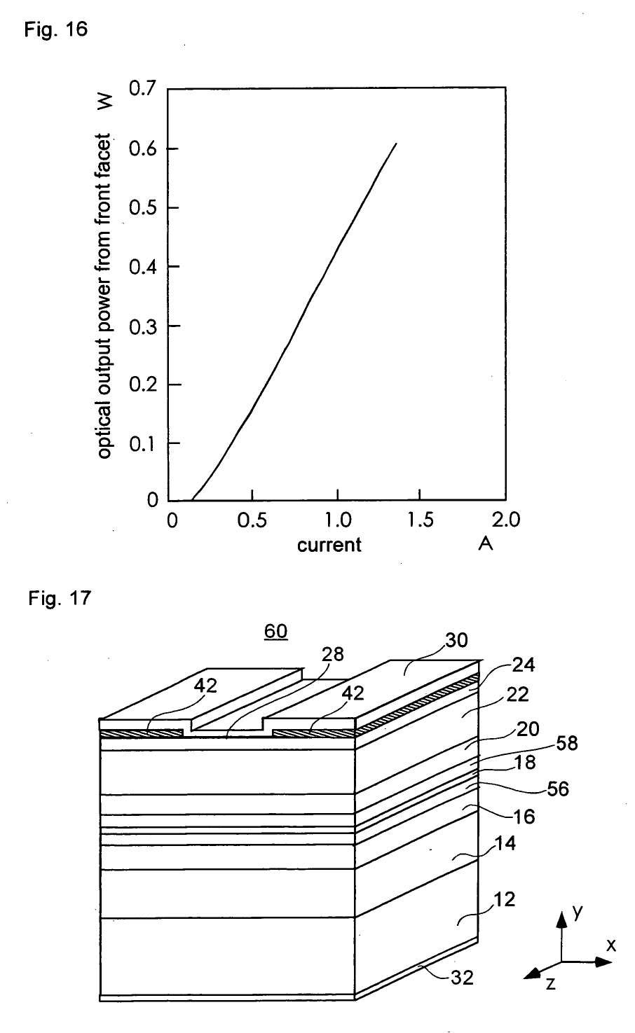

FIG. 16 is a graph that shows optical output power—current characteristics of another experimental sample of a semiconductor laser according to one embodiment of the present invention.

The semiconductor laser as this fourth experimental sample, is of essentially the same configuration as for the foregoing third experimental sample, except that an n-side guide layer and a p-side guide layer are both 600 nm thick.

The semiconductor laser as the fourth experimental sample, exhibits favorable characteristics at a threshold current of 0.128 A, an operating current of 1.365 A for a 0.6-W output power, and a slope efficiency of 0.485 W/A.

Also, an emission wavelength at the 0.6-W output power is 945.3 nm. Since the guide layers in the semiconductor laser as the fourth experimental sample are thicker than the guide layers of the semiconductor laser as the third experimental sample, a greater confinement ratio of light is achieved in undoped regions. Consequently, the semiconductor laser as the fourth experimental sample, compared with the semiconductor laser as the third experimental sample, is small in threshold current and high in slope efficiency.

Fourth Variation

FIG. 17 is a perspective view of a variation of the semiconductor laser according to one embodiment of the present invention.

In FIG. 17, semiconductor laser 60 is essentially the same as the semiconductor laser 54 in terms of basic configuration. However, the semiconductor laser 60 differs in current constriction structure.

The current constriction structure in the semiconductor laser 60 is essentially the same as for the first variation of the first embodiment. Other structural aspects of the semiconductor laser 60 are the same as for the semiconductor laser 54.

The semiconductor laser 60 has advantageous effects in that it yields effects equivalent to those of the semiconductor laser 54, and in that since the current constriction structure can be formed using low-price process apparatus, the semiconductor laser 60 itself can be provided at a low price.

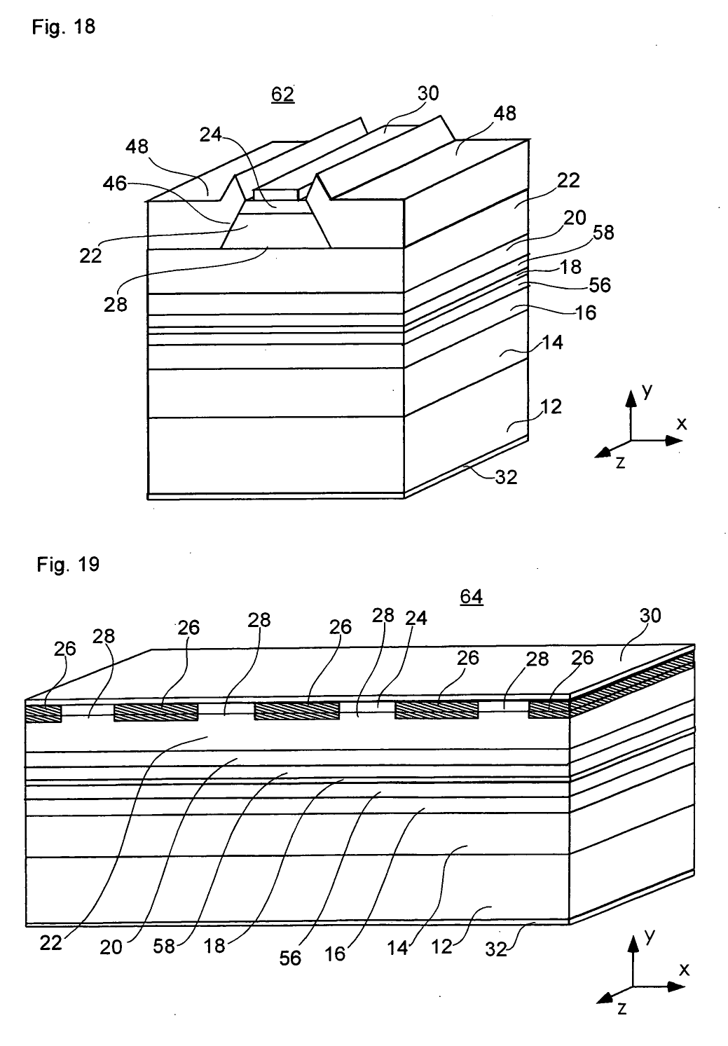

Fifth Variation FIG. 18 is a perspective view of a variation of the semiconductor laser according to one embodiment of the present invention.

In FIG. 18, semiconductor laser 62 is essentially the same as the semiconductor laser 54 in terms of basic configuration. However, the semiconductor laser 62 differs in current constriction structure.

The current constriction structure in the semiconductor laser 62 is essentially the same as for the second variation of the first embodiment. Other structural aspects of the semiconductor laser 62 are the same as for the semiconductor laser 54.

The semiconductor laser 62 has advantageous effects in that it yields effects equivalent to those of the semiconductor laser 54, and in that since the current constriction structure can be formed in a crystal growth process, wafer processing can be simplified and the semiconductor laser 62 itself can be provided at a low price.

Sixth Variation

FIG. 19 is a perspective view of a variation of the semiconductor laser according to one embodiment of the present invention.

In FIG. 19, semiconductor laser 64 is essentially the same as the semiconductor laser 54 in terms of basic configuration. However, the semiconductor laser 64 differs from the semiconductor laser 54 in that the number of proton-injected regions is increased to form a plurality of current paths 28. In this respect, the sixth variation is of the same configuration as for the third variation of the first embodiment. An array-type semiconductor laser structure with even more arrays can be manufactured by extending the semiconductor layer 64 dimensionally in an x-direction thereof and further increasing the number of proton-injected regions 26. Increasing the number of arrays enables a larger-output power semiconductor laser to be constructed.

As can be seen from the above, in the semiconductor laser according to the present embodiment, a first barrier layer of undoped GaAs_{1-w}P_{w} (0.2>w>0) is disposed between the active layer and the first optical waveguide layer and between the active layer and the second optical waveguide layer. Accordingly, it is possible to enhance a confinement ratio of light in an active-layer section of optical intensity distribution of the semiconductor laser and hence to confine the light effectively in undoped regions. It is possible even to effectively construct a semiconductor laser device that operates at a small current and is high in efficiency and in reliability.

In addition, since providing a first barrier layer enhances the effective refractive index defined by the first barrier layer and guide layers, it becomes possible to raise the flexibility of the semiconductor laser configuration that enhances the optical intensity rate in the undoped regions, and hence to easily construct a semiconductor laser device that operates at a small current and is high in efficiency and in reliability.

### Third Embodiment

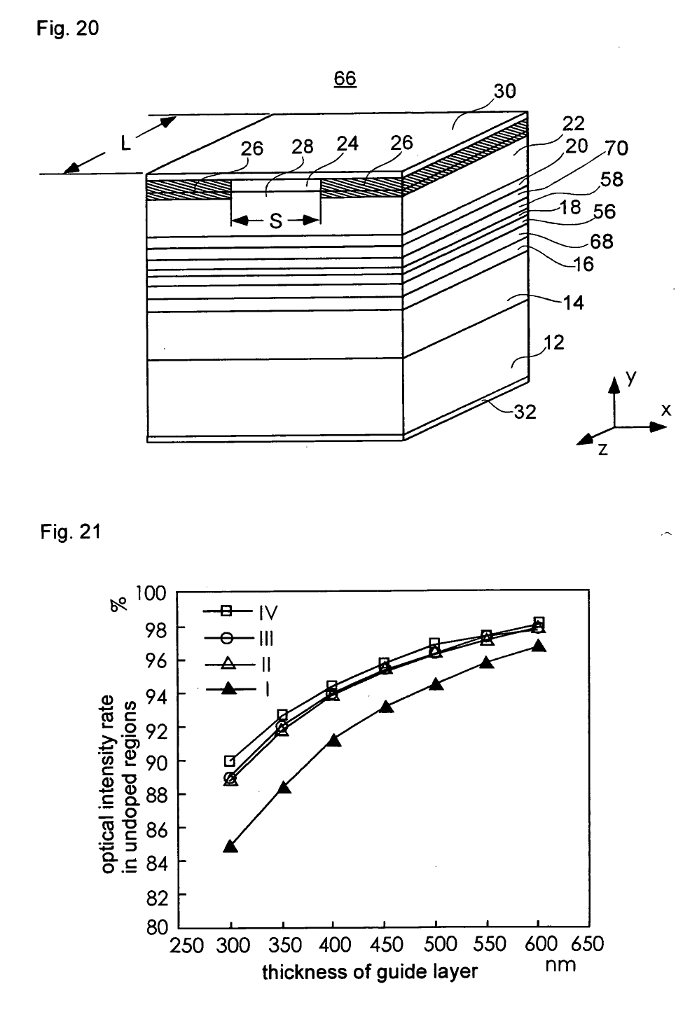

FIG. 20 is a perspective view of a semiconductor laser according to one embodiment of the present invention.

Semiconductor laser 66 in FIG. 20 differs from the semiconductor laser 54 of the second embodiment in that in addition to an n-side first barrier layer 56, an n-side second barrier layer 68 is further provided as a second barrier layer between an n-side guide layer 16 and an active layer 18, and in that in addition to a p-side first barrier layer 58, a p-side second barrier layer 70 is further provided as a second barrier layer between the active layer 18 and a p-side guide layer 20.

In the semiconductor laser 66 of the present third embodiment, the n-side second barrier layer 68 is provided between the n-side guide layer 16 and the n-side first barrier layer 56. Also, the p-side second barrier layer 70 is provided between the p-side first barrier layer 58 and the p-side guide layer 20. In the semiconductor laser 66, the n-side second barrier layer 68 and the p-side second barrier layer 70 are formed of i-GaAs, an undoped semiconductor, and these two second barrier layers have a thickness of 8 nm, for example.

As with those of the semiconductor laser 54 of the second embodiment, the n-side first barrier layer 56 and the p-side first barrier layer 58 are formed of i-GaAs_{0.88}P_{0.12}. Unlike the n-side first barrier layer 56 and p-side first barrier layer 58 of the semiconductor laser 54, however, those of the semiconductor laser 66 both have a thickness of 8 nm, for example. Other structural aspects of the semiconductor laser 66 are the same as for the semiconductor laser 54.

The semiconductor laser 66 of the above configuration in the present third embodiment includes the GaAs second barrier layer in addition to the GaAsP first barrier layer (hereinafter, when the n-side second barrier layer 68 and the p-side second barrier layer 70 are collectively discussed, these layers are referred to simply as the “second barrier layers”). The GaAs second barrier layers are completely lattice-matched to an n-GaAs substrate 12, so even if these layers are made thick, the active layer 18 is not strained. Compared with the semiconductor laser having the configuration of the first embodiment or the second embodiment, the semiconductor laser 66 can improve a confinement ratio of light in the active layer 18. Accordingly, a stronger interaction between light and carriers can be obtained for reduced threshold current.

FIG. 21 is a graph showing optical intensity rates in undoped regions of the semiconductor laser according to one embodiment of the present invention, versus thicknesses of the guide layers in the laser.

FIG. 21 assumes the configuration of the semiconductor laser 66 as a basic configuration, and for an active-layer structure with a single-quantum-well layer formed of In_{0.07}Ga_{0.93}As, calculation conditions on each of the curves I (▴), II (Δ), III (∘), and IV (□) shown in the figure are the same as the conditions described in FIG. 4 of the first embodiment.

A horizontal axis in FIG. 21 indicates guide layer thickness, and this guide layer thickness is the thickness of the n-type and p-type guide layers 16 and 20, respectively, based on the assumption that both guide layers are of the same thickness.

A vertical axis indicates a optical intensity rate of undoped regions, and this rate is a optical intensity distribution rate of the light included in the n-side guide layer 16, n-side second barrier layer 68, n-side first barrier layer 56, active layer 18, p-side first barrier layer 58, p-side second barrier layer 70, and p-side guide layer 20 that are the undoped regions.

As can be seen from FIG. 21, when an n-type cladding layer 14 and a p-type cladding layer 22 have an Al-content ratio of 0.10 in AlGaInP, the thickness of the active layer 18 is 6 nm, and the guide layer thickness is 350 nm or more, the optical intensity rate of the undoped regions is in excess of 88%.

When the thickness of the active layer 18 is 6 nm or more, the n-type cladding layer 14 and the p-type cladding layer 22 have an Al-content ratio of 0.15 in AlGaInP, and the guide layer thickness is 350 nm or more, the optical intensity rate of the undoped regions is about 92% or more.

The above is due to the facts that because of the GaAs second barrier layers being completely lattice-matched to the n-GaAs substrate 12, even if these layers are made thick, the active layer 18 is not strained, and thus that the confinement ratio of light in the active layer 18 is enhanced.

In addition, changing the thickness of the active layer 18 causes essentially no change in the optical intensity rate of the undoped regions. This means that similarly to the second embodiment, the optical intensity rate of the semiconductor laser is defined by the difference between the refractive index determined mainly by the barrier layers and the guide layers, and a refractive index of the cladding layers.

The calculation conditions in FIG. 21 assume that both the n-side and p-side GaAs second barrier layers are 8 nm thick. The second barrier layers affect the optical intensity distribution in the undoped regions of the semiconductor laser in terms of the effective refractive index defined by the refractive indices and layer thicknesses of these second barrier layers. Increasing the thicknesses of the second barrier layers also increases the effective refractive index. When the respective thicknesses of the n-side second barrier layer 68 and the p-side second barrier layer 70 exceed 8 nm, therefore, assigning a guide layer thickness of at least 350 nm for a layer thickness of at least 6 nm of the active layer 18 and an Al-content ratio of 0.15 of the n-type cladding layer 14 and p-type cladding layer 22 in AlGaInP naturally makes the optical intensity rate in the undoped regions exceed 90%.

Also, even when the respective thicknesses of the second barrier layers are less than 8 nm, the optical intensity rate in the undoped regions can be increased above 90% at the guide layer thickness of at least 350 nm by raising the respective thicknesses of the n-side first barrier layer 56 and the p-side first barrier layer 58 or raising the Al-content ratio of the n-type cladding layer 14 and p-type cladding layer 22 in AlGaInP to a value greater than 0.15.

For example, the curves II, III, and IV in FIG. 21 apply when an Al-content ratio of 0.15 is assigned as an example. Assigning an Al-content ratio greater than 0.15, however, produces greater differences in refractive index between the n-type cladding layer 14 and the n-side guide layer 16 and between the p-side guide layer 20 and the p-type cladding layer 22. Even when the respective thicknesses of the second barrier layers are less than 8 nm, therefore, the optical intensity rate in the undoped regions can be increased above 90% at the guide layer thickness of at least 350 nm.

Providing in this way the n-side second barrier layer 68 between the n-side guide layer 16 and the n-side first barrier layer 56, and the p-side second barrier layer 70 between the p-side first barrier layer 58 and the p-side guide layer 20, makes it possible to increase the barrier layer thicknesses without strains applied to the active layer 18. The confinement ratio of light in the active layer 18 can therefore be enhanced. This produces a stronger interaction between light and carriers, thus reducing a threshold current.

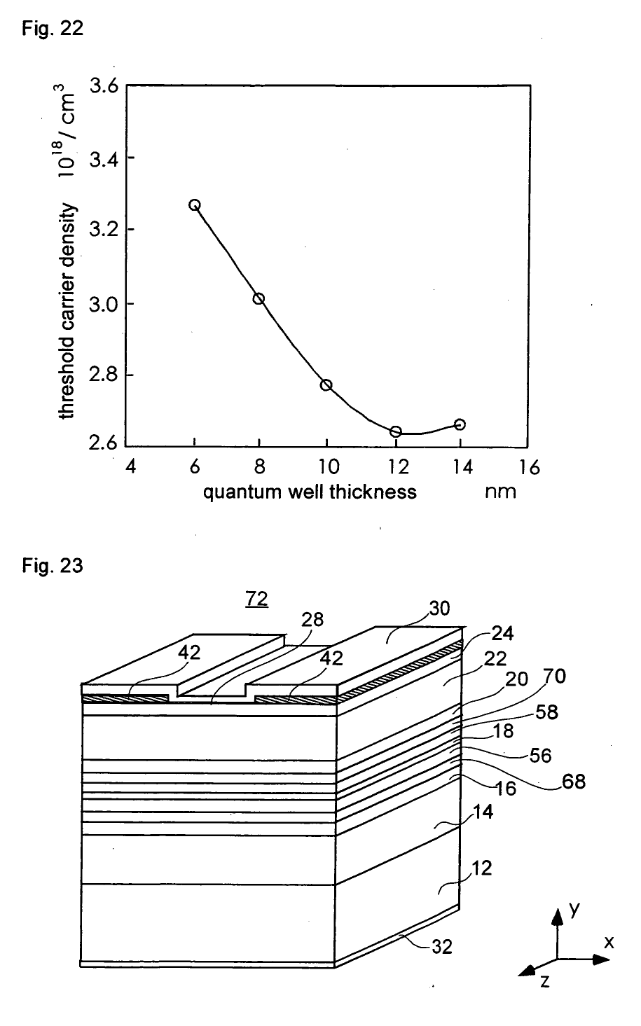

FIG. 22 is a graph showing a threshold carrier density in the semiconductor laser according to one embodiment of the present invention, versus a quantum well thickness of the laser.

That is to say, FIG. 22 shows quantum-well layer thickness dependence of the threshold carrier density required for laser light emission of the semiconductor laser.

Calculation conditions in connection with FIG. 22 are based on the configuration of the semiconductor laser 66, and assume that the semiconductor laser includes an n-side guide layer 16 and a p-side guide layer 20 both formed into a thickness of 600 nm as an example. The calculation conditions also assume that the semiconductor laser has a front reflectance of 13%, a rear reflectance of 98%, a cavity length of 1000 μm, and an internal loss of 0.8 cm⁻¹.

As shown in FIG. 22, similarly to the first embodiment and the second embodiment, a sufficient gain necessary for laser light emission can be obtained if a total thickness of the quantum well layer is at least 6 nm.

Also, similarly to the first embodiment and the second embodiment, since the threshold carrier density is minimized in vicinity of a 12-nm quantum-well layer thickness, the threshold current becomes a minimum by formation of an active layer of a single-quantum-well structure with a layer thickness of about 12 nm, or by formation of active layers of a multiple-quantum-well structure with a total quantum-well layer thickness of about 12 nm. The reason for that is the same as the reason set forth in the first embodiment.

Seventh Variation

FIG. 23 is a perspective view of a variation of the semiconductor laser according to one embodiment of the present invention.

In FIG. 23, semiconductor laser 72 is essentially the same as the semiconductor layer 66 in terms of basic configuration. However, the semiconductor laser 72 differs in current constriction structure.

The current constriction structure in the semiconductor laser 72 is essentially the same as for the first variation of the first embodiment. Other structural aspects of the semiconductor laser 72 are the same as for the semiconductor laser 66.

The semiconductor laser 72 has advantageous effects in that it yields effects equivalent to those of the semiconductor laser 66, and in that since the current constriction structure can be formed using low-price process apparatus, the semiconductor laser 72 itself can be provided at a low price.

Eighth Variation

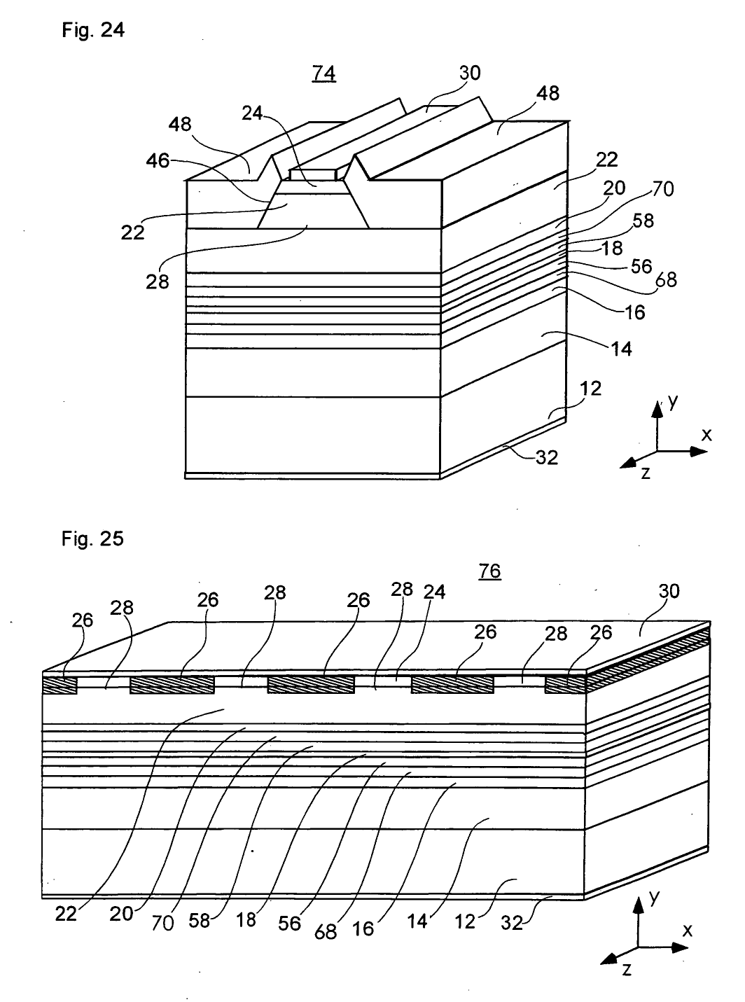

FIG. 24 is a perspective view of a variation of the semiconductor laser according to one embodiment of the present invention.

In FIG. 24, semiconductor laser 74 is essentially the same as the semiconductor layer 66 in terms of basic configuration. However, the semiconductor laser 74 differs in current constriction structure.

The current constriction structure in the semiconductor laser 74 is essentially the same as for the second variation of the first embodiment. Other structural aspects of the semiconductor laser 74 are the same as for the semiconductor laser 66.

The semiconductor laser 74 has advantageous effects in that it yields effects equivalent to those of the semiconductor laser 66, and in that since the current constriction structure can be formed in a crystal growth process, wafer processing can be simplified and the semiconductor laser 74 itself can be provided at a low price.

Ninth Variation

FIG. 25 is a perspective view of a variation of the semiconductor laser according to one embodiment of the present invention.

In FIG. 25, semiconductor laser 76 is essentially the same as the semiconductor layer 66 in terms of basic configuration. However, the semiconductor laser 76 differs from the semiconductor layer 66 in that the number of proton-injected regions is increased to form a plurality of current paths 28. In this respect, the ninth variation is of the same configuration as for the third variation of the first embodiment. An array-type semiconductor layer structure with even more arrays can be manufactured by extending the semiconductor layer 76 dimensionally in an x-direction thereof and further increasing the number of proton-injected regions 26. Increasing the number of arrays enables a larger-output power semiconductor laser to be constructed.

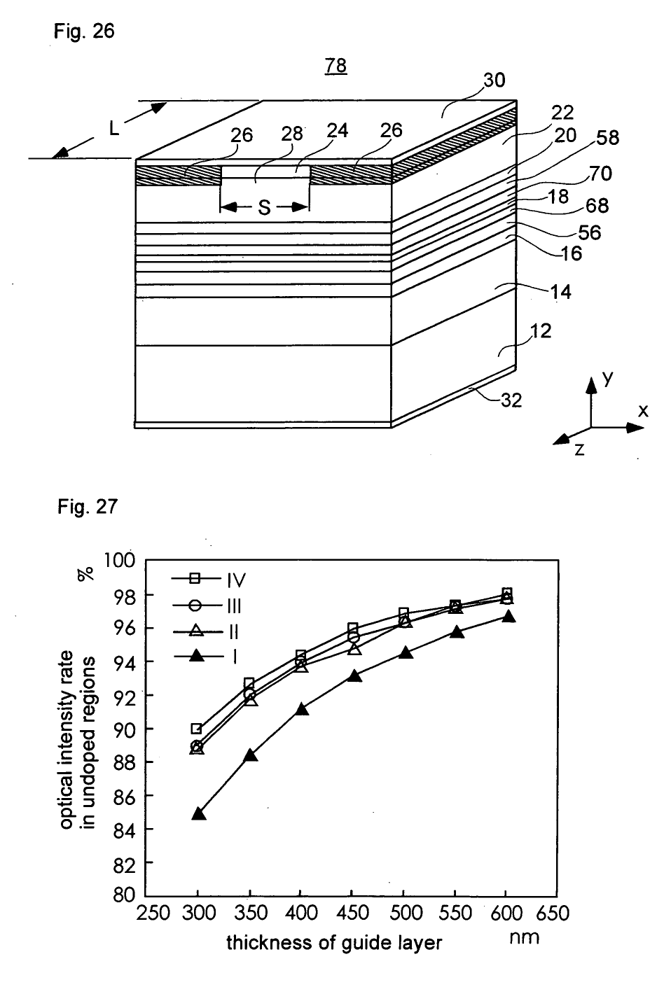

FIG. 26 is a perspective view of another semiconductor laser according to one embodiment of the present invention.

Semiconductor laser 78 in FIG. 26 is the same as the foregoing semiconductor laser 66 in that in addition to an n-side first barrier layer 56, an n-side second barrier layer 68 is further provided as a second barrier layer between an n-side guide layer 16 and an active layer 18, and in that in addition to a p-side first barrier layer 58, a p-side second barrier layer 70 is further provided as a second barrier layer between the active layer 18 and a p-side guide layer 20.

However, the semiconductor laser 78 differs from the semiconductor laser 66 in that the n-side second barrier layer 68 is provided between the n-side first barrier layer 56 and the active layer 18, and in that the p-side second barrier layer 70 is provided between the active layer 18 and the p-side first barrier layer 58. In the semiconductor laser 78, the n-side second barrier layer 68 and the p-side second barrier layer 70 are formed of i-GaAs, an undoped semiconductor, and these two second barrier layers have a thickness of 8 nm, for example. Also, the n-side first barrier layer 56 and the p-side first barrier layer 58 are formed of i-GaAs_{0.88}P_{0.12}, an undoped semiconductor, and these two first barrier layers also have a thickness of 8 nm, for example. Other structural aspects of the semiconductor laser 78 are the same as for the semiconductor laser 66.

As with the semiconductor laser 66, therefore, the semiconductor laser 78, compared with the semiconductor laser having the configuration of the first embodiment or the second embodiment, can improve a confinement ratio of light in the active layer 18. Accordingly, a stronger interaction between light and carriers can be obtained for reduced threshold current.

Also, in the semiconductor laser 78, the lattice-matched i-GaAs n-side second barrier layer 68 is inserted between the active layer 18 formed of In_{0.07}Ga_{0.93}As and impressed with a compressive strain, and the i-GaAs_{0.88}P_{0.12} n-side first barrier layer 56 impressed with a tensile strain. Similarly, the i-GaAs p-side second barrier layer 70 lattice-matched to an n-GaAs substrate 12 is inserted between the active layer 18 formed of In_{0.07}Ga_{0.93}As and impressed with a compressive strain, and the i-GaAs_{0.88}P_{0.12} p-side first barrier layer 58 impressed with a tensile strain. The active layer 18, the n-side first barrier layer 56, and the p-side first barrier layer 58 can therefore be made thick.

Compared with the semiconductor laser 66, therefore, the semiconductor laser 78 can further improve the confinement ratio of light in the active layer 18. Accordingly, an even stronger interaction between light and carriers can be obtained for further reduced threshold current.

Additionally, an overflow of carrier electrons can be prevented by providing the GaAs n-side second barrier layer 68 between the active layer 18 and the GaAsP n-side first barrier layer 56 such that the barrier layer 56 of a great bandgap is apart from the active layer 18, and/or providing the p-side second barrier layer 70 between the active layer 18 and the GaAsP p-side first barrier layer 58 such that the barrier layer 58 of a great bandgap is apart from the active layer 18.

FIG. 27 is a graph showing optical intensity rates in undoped regions of the above semiconductor laser according to one embodiment of the present invention, versus thicknesses of the guide layers in the laser.

FIG. 27 assumes the configuration of the semiconductor laser 78 as a basic configuration, and for an active-layer structure with a single-quantum-well layer formed of In_{0.07}Ga_{0.93}As, calculation conditions on each of the curves I (▴), II (Δ), III (∘), and IV (□) shown in the figure are the same as the conditions described in FIG. 4 of the first embodiment.

A horizontal axis in FIG. 27 indicates guide layer thickness, and this guide layer thickness is the thickness of the n-side guide layers 16 and p-side guide layers 20, respectively, based on the assumption that both guide layers are of the same thickness.

A vertical axis indicates a optical intensity rate of undoped regions, and this rate is a optical intensity distribution rate of the light included in the n-side guide layer 16, n-side first barrier layer 56, n-side second barrier layer 68, active layer 18, p-side second barrier layer 70, p-side first barrier layer 58, and p-side guide layer 20 that are the undoped regions.

As can be seen from FIG. 27, when an n-type cladding layer 14 and a p-type cladding layer 22 have an Al-content ratio of 0.10 in AlGaInP, the thickness of the active layer 18 is 6 nm or more, and the guide layer thickness is 350 nm or more, the optical intensity rate of the undoped regions is in excess of 88%.

When the thickness of the active layer 18 is 6 nm or more, the n-type cladding layer 14 and the p-type cladding layer 22 have an Al-content ratio of 0.15 in AlGaInP, and the guide layer thickness is 350 nm or more, the optical intensity rate in the undoped regions is about 92% or more.

The above is due to the facts that because of the GaAs second barrier layers being completely lattice-matched to the n-GaAs substrate 12, even if these layers are made thick, the active layer 18 is not strained, and thus that the confinement ratio of light in the active layer 18 is enhanced.

In addition, changing the thickness of the active layer 18 causes essentially no change in the optical intensity rate of the undoped regions. This means that similarly to the second embodiment, the optical intensity rate of the semiconductor laser is defined by the difference between the refractive index determined mainly by the barrier layers and the guide layers, and a refractive index of the cladding layers.

The calculation conditions in FIG. 27 assume that both the n-side and p-side GaAs second barrier layers are 8 nm thick. The second barrier layers affect the optical intensity distribution in the undoped regions of the semiconductor laser in terms of the effective refractive index defined by the refractive indices and layer thicknesses of these second barrier layers. Increasing the thicknesses of the second barrier layers also increases the effective refractive index. When the respective thicknesses of the n-side second barrier layer 68 and the p-side second barrier layer 70 exceed 8 nm, therefore, assigning a guide layer thickness of at least 350 nm for a layer thickness of at least 6 nm of the active layer 18 and an Al-content ratio of 0.15 of the n-type cladding layer 14 and p-type cladding layer 22 in AlGaInP naturally makes the optical intensity rate in the undoped regions exceed 90%.

Also, even when the respective thicknesses of the second barrier layers are less than 8 nm, the optical intensity rate in the undoped regions can be increased above 90% at the guide layer thickness of at least 350 nm by raising the respective thicknesses of the n-side first barrier layer 56 and the p-side first barrier layer 58 or raising the Al-content ratio of the n-type cladding layer 14 and p-type cladding layer 22 in AlGaInP to a value greater than 0.15.

For example, the curves II, III, and IV in FIG. 27 apply when an Al-content ratio of 0.15 is assigned as an example. Assigning an Al-content ratio greater than 0.15, however, produces greater differences in refractive index between the n-type cladding layer 14 and the n-side guide layer 16 and between the p-side guide layer 20 and the p-type cladding layer 22. Even when the respective thicknesses of the second barrier layers are less than 8 nm, therefore, the optical intensity rate in the undoped regions can be increased above 90% at the guide layer thickness of at least 350 nm.

Needless to say, when there is not the limitation that at least 90% of the light should be confined in the undoped regions, no restrictions need to be imposed on the layer thickness of GaAsP and a P-content ratio therein. For example, if the n-side and p-side second barrier layers of GaAs are formed into a thickness of 5 nm or less and the n-side and p-side first layers of GaAsP are formed into a thickness of approximately 10 nm, the semiconductor laser of this configuration will only approach the semiconductor laser of the second embodiment in terms of characteristics.

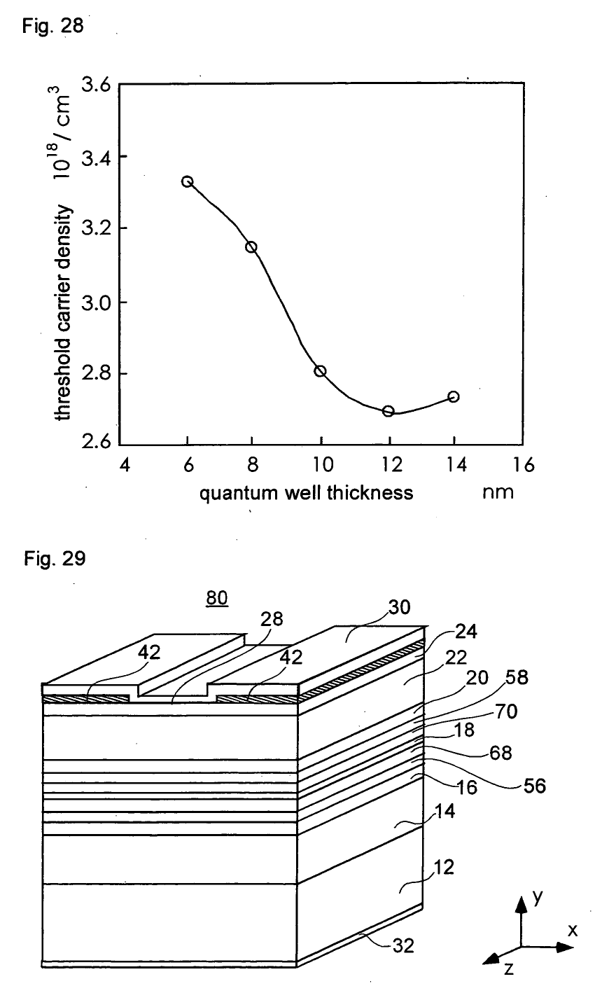

FIG. 28 is a graph showing a threshold carrier density in the foregoing semiconductor laser according to one embodiment of the present invention, versus a quantum well thickness of the laser.

That is to say, FIG. 28 shows quantum-well layer thickness dependence of the threshold carrier density required for laser light emission of the semiconductor laser.

Calculation conditions in connection with FIG. 28 are based on the configuration of the semiconductor laser 78, and assume that both the semiconductor laser includes an n-side guide layer 16 and a p-side guide layer 20 both formed into a thickness of 600 nm as an example. The calculation conditions also assume that the semiconductor laser has a front reflectance of 13%, a rear reflectance of 98%, a cavity length of 1000 μm, and an internal loss of 0.8 cm⁻¹.

As shown in FIG. 28, similarly to the first embodiment and the second embodiment, a sufficient gain necessary for laser light emission can be obtained if a total thickness of the quantum well layer is at least 6 nm.

Also, similarly to the first embodiment and the second embodiment, since the threshold carrier density is minimized in vicinity of a 12-nm quantum-well layer thickness, the threshold current becomes a minimum by formation of an active layer of a single-quantum-well structure with a layer thickness of about 12 nm, or by formation of active layers of a multiple-quantum-well structure with a total quantum-well layer thickness of about 12 nm. The reason for that is the same as the reason set forth in the first embodiment.

Tenth Variation

FIG. 29 is a perspective view of a variation of the semiconductor laser according to one embodiment of the present invention.

In FIG. 29, semiconductor laser 80 is essentially the same as the semiconductor layer 78 in terms of basic configuration. However, the semiconductor laser 80 differs in current constriction structure.

The current constriction structure in the semiconductor laser 80 is essentially the same as for the first variation of the first embodiment. Other structural aspects of the semiconductor laser 80 are the same as for the semiconductor laser 78.

The semiconductor laser 80 has advantageous effects in that it yields effects equivalent to those of the semiconductor laser 78, and in that since the current constriction structure can be formed using inexpensive process apparatus, the semiconductor laser 80 itself can be provided at a low price.

Eleventh Variation

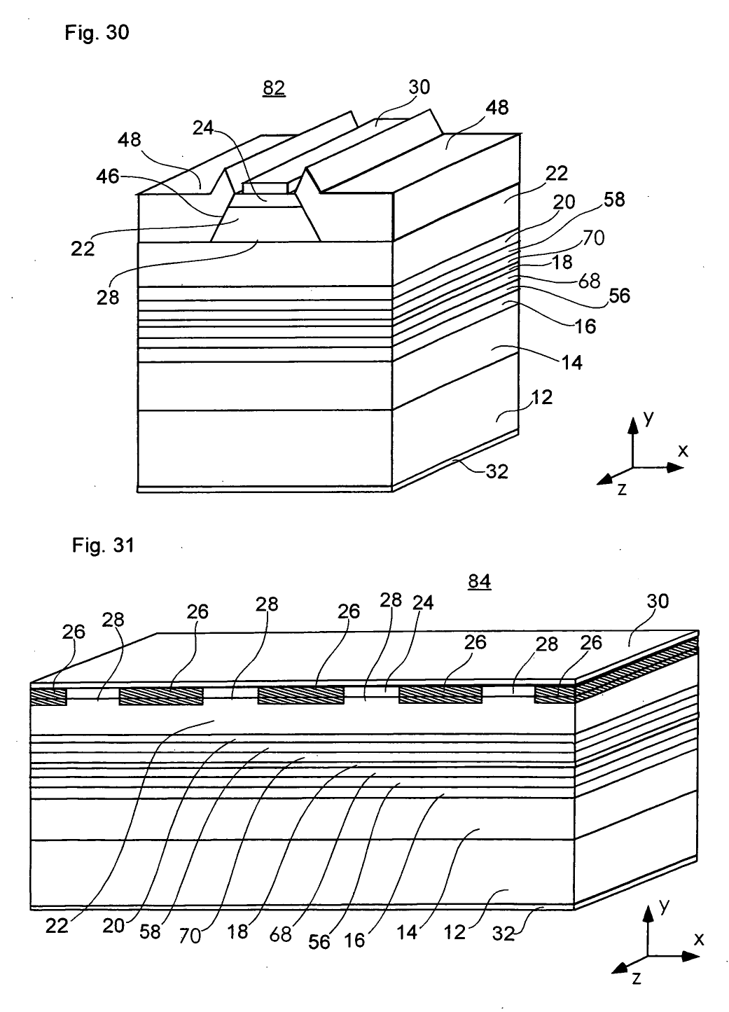

FIG. 30 is a perspective view of a variation of the semiconductor laser according to one embodiment of the present invention.

In FIG. 30, semiconductor laser 82 is essentially the same as the semiconductor layer 78 in terms of basic configuration. However, the semiconductor laser 82 differs in current constriction structure.

The current constriction structure in the semiconductor laser 82 is essentially the same as for the second variation of the first embodiment. Other structural aspects of the semiconductor laser 82 are the same as for the semiconductor laser 78.

The semiconductor laser 82 has advantageous effects in that it yields effects equivalent to those of the semiconductor laser 78, and in that since the current constriction structure can be formed in a crystal growth process, wafer processing can be simplified and the semiconductor laser 82 itself can be provided at a low price.

Twelfth Variation

FIG. 31 is a perspective view of a variation of the semiconductor laser according to one embodiment of the present invention.

In FIG. 31, semiconductor laser 84 is essentially the same as the semiconductor layer 78 in terms of basic configuration. However, the semiconductor laser 84 differs from the semiconductor layer 78 in that the number of proton-injected regions is increased to form a plurality of current paths 28. In this respect, the twelfth variation is of the same configuration as for the third variation of the first embodiment. An array-type semiconductor laser structure with even more arrays can be manufactured by extending the semiconductor layer 84 dimensionally in an x-direction thereof and further increasing the number of proton-injected regions 26. Increasing the number of arrays enables a larger-output power semiconductor laser to be constructed.

As described above, in the semiconductor laser according to the present embodiment, a second barrier layer of undoped GaAs is further disposed between the active layer and the first optical waveguide layer and between the active layer and the second optical waveguide layer, respectively. Accordingly, because of the second barrier layers being completely lattice-matched to a first electroconductive type of GaAs substrate, even if these layers are made more thick, the active layer is not strained and thus a confinement ratio of light in the active layer is further enhanced. Hence, an stronger interaction between light and carriers can be obtained for further reduced threshold current. It is possible even to effectively construct a semiconductor laser device that operates at a small current and is high in efficiency and in reliability.

Furthermore, the second barrier layers are located between the active layer and first barrier layers. Therefore, a lattice-matched i-GaAs n-side second barrier layer is inserted between the active layer impressed with a compressive strain, and the first barrier layer impressed with a tensile strain, Similarly, a second barrier layer lattice-matched to the GaAs substrate is inserted between the active layer formed of In_{0.07}Ga_{0.93}As and impressed with a compressive strain, and the i-GaAs_{0.88}P_{0.12} p-side first barrier layer impressed with a tensile strain. The active layer and first barrier layers can therefore be made thick, and this enables the confinement ratio of light in the active layer 18 to be further improved. Accordingly, an even stronger interaction between light and carriers can be obtained for further reduced threshold current. Additionally, an overflow of carrier electrons can be prevented by providing the second barrier layers adjacently to the active layer such that the first barrier layer of a great bandgap is apart from the active layer. Hence, electrons contributory to derived emission can be generated in great quantities at the active layer, and decreases in internal quantum efficiency can be suppressed. This, in turn, enables decreases in slope efficiency to be suppressed and a highly efficient semiconductor laser device to be constructed.

The above description of the present embodiment assumes that the semiconductor laser operates at an emission wavelength of about 940 nm, so an In-content ratio in the InGaAs forming the active layer is set to be 0.07 and a thickness of the active layer is set to be about 12 nm. However, changing either the In-content ratio or thickness of the active layer or both the In-content ratio and the layer thickness enables the semiconductor laser to emit at a different wavelength. Changing the In-content ratio, in particular, affects the emission wavelength significantly.

For example, if the thickness of the active layer is fixed at 12 nm for its In-content ratio of 0.04, 0.14, 0.205, or 0.235, the emission wavelength of the semiconductor laser will correspondingly change to about 900 nm, 980 nm, 1,060 nm, or 1,100 nm, respectively.

Making the active layer thicker than 12 nm will change the emission wavelength to be a longer one. Conversely, making the active layer thinner than 12 nm will change the emission wavelength to be a shorter one. In other words, a semiconductor laser with an emission wavelength of 900 nm or more, but up to 1100 nm, can be constructed by changing the In-content ratio and the layer thickness appropriately.

Also, the thickness of the InGaP guide layers is not limited to the values shown by way of example in the above description, and the thickness of the guide layers can be set in a wider range by changing the Al-content ratio of these layers in AlGaInP.

For example, increasing the Al-content ratio above 0.15 produces greater differences in refractive index between the cladding layers and the guide layers, so even if the guide layers are made thinner, optical intensity distribution of light can be included in undoped regions. Conversely, even if reducing the Al-content ratio below 0.15, increasing the guide layer thickness makes it possible to include the optical intensity distribution of light in the undoped regions.

A P-content ratio and layer thickness of the GaAsP barrier layers are not limited to the values shown by way of example in the above description, either. For example, increasing the P-content ratio with increasing the layer thickness, increasing the layer thickness without changing the P-content ratio, or increasing the P-content ratio without increasing the layer thickness makes it possible to improve the confinement ratio of light in the active layer and reduce threshold carrier density.

Additionally, the layer thickness of the GaAs barrier layers is not limited to the values shown by way of example in the above description, either. Increasing the layer thickness makes it possible to improve the confinement ratio of light in the active layer and reduce threshold carrier density.

Furthermore, although the foregoing description assumes AlGaInP cladding layers with an Al-content ratio of 0.15 and a layer thickness of 0.7 μm, the Al-content ratio and the layer thickness are not limited to these values.

For example, if the Al-content ratio is increased above 0.15, since a large portion of light generated at the active layer will be included in the undoped regions, a rate at which the light is likely to leak into the GaAs substrate and/or the GaAs contact layer will consequently decrease. In this case, even if the thickness of the cladding layers is reduced below 0.7 μm, absorption of the light into the GaAs substrate and/or the GaAs contact layer will not increase, which will enable the reduction of the cladding layer thickness. For this reason, thinning down the cladding layers improves a heat sink effect, reduces threshold current, and improves efficiency.

Besides, while a current constriction structure based on proton injection, a current constriction structure using a dielectric film, and a current constriction structure using an n-type semiconductor have been described above as the semiconductor laser structures according to the present invention, these semiconductor laser structures do not limit the invention and for example, a simplified ridge structure or a ridge structure with a semiconductor layer embedded therein for current constriction can also yield equivalent advantageous effects.

### Fourth Embodiment

The configuration of a semiconductor laser that forms a base for calculation in connection with FIG. 14 is basically the same as for the semiconductor laser 54. However, an n-side guide layer 16 and a p-side guide layer 20 are formed of i-In_{0.49}Ga_{0.51}P, which, provided that lattice-matching to GaAs is established, can take any In-content ratio that satisfies 1>u>0.

Also, an n-side first barrier layer 56 and a p-side first barrier layer 58 are formed of i-GaAs_{0.9}P_{0.1} whose P-content ratio in GaAsP is 0.1, and both the n-side first barrier layer 56 and the p-side first barrier layer 58 are 8 nm thick.

In this case, an active layer 18 is formed of In_{0.07}Ga_{0.93}As with an In-content ratio of 0.07 to obtain a semiconductor laser emission wavelength of 940 nm.

However, for use as an pumping light source in Yb-doped fiber laser, Er-doped fiber amplifier, or other applications, the emission wavelength needs to be increased to, for example, 1.06 μm, so the In-content ratio can be such that it satisfies 0.24>v>0. Also, the active layer 18 of the semiconductor laser 10 is, in this case, formed into a single-quantum-well structure as an example.

FIG. 14 shows the relationship of threshold carrier density with respect to quantum-well layer thickness, obtained by changing a quantum-well layer thickness of an active layer 18 formed into a single-quantum-well structure, and calculating changes in threshold carrier density. This figure assumes a semiconductor laser configuration in which respective materials and layer thicknesses of an n-side guide layer 16, a p-side guide layer 20, an n-side first barrier layer 56, and a p-side first barrier layer 58 are set as mentioned above.

The present fourth embodiment is an expansion of a semiconductor laser configuration having a quantum-well layer(s) thicker than the n-side first barrier layer 56 and the p-side first barrier layer 58, the semiconductor laser being one of the semiconductor laser configurations that underlie the calculation results in FIG. 14 of the second embodiment.

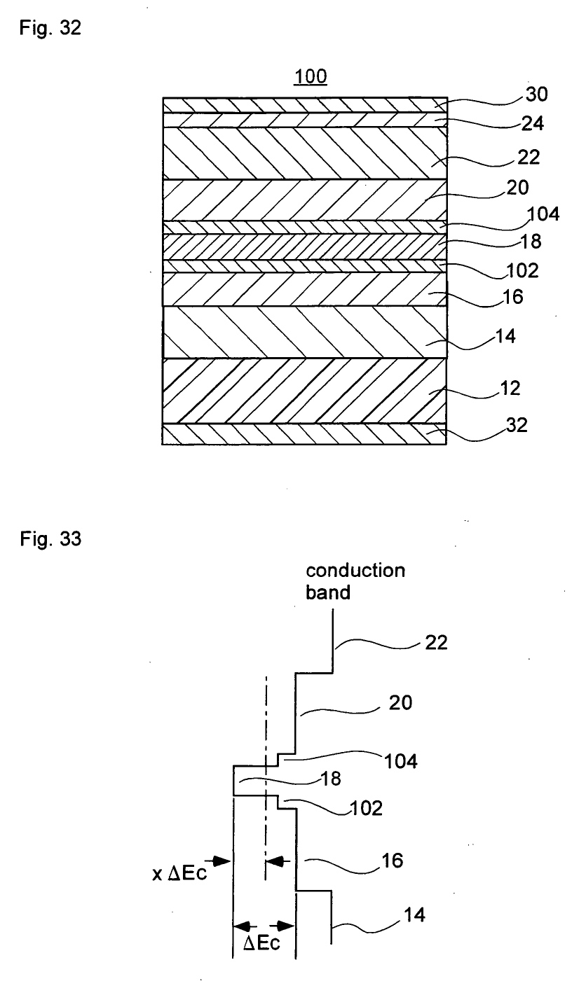

FIG. 32 is a sectional view of a semiconductor laser according to one embodiment of the present invention. That is, FIG. 32 is a sectional view of the semiconductor laser in a section orthogonal to a wave-conducting direction of light, and speaking in an associated relationship with respect to the semiconductor laser of FIG. 11, this sectional view is equivalent to one in a section orthogonal to a z-axis in this semiconductor laser. The semiconductor laser sectional views shown in FIGS. 39 onward are also ones in essentially the same section.

In FIG. 32, semiconductor laser 100 includes the following layers disposed in order on an n-GaAs semiconductor substrate 12: an n-type cladding layer 14, an n-side guide layer 16, an n-side enhanced layer 102 as a first semiconductor layer, an active layer 18 disposed in in contact with the n-side enhanced layer 102, a p-side enhanced layer 104 disposed as another first semiconductor layer in contact with the active layer 18, a p-side guide layer 20, a p-side cladding layer 22, and a contact layer 24.

The surface of the contact layer 24 has a p-electrode 30 formed of a gold film, and a reverse side of the n-GaAs substrate 12 has an n-electrode 32 formed of a gold film.

The n-type cladding layer 14 is formed of, for example, n-(Al_{0.3}Ga_{0.7})_{0.5}In_{0.5}P, and has a thickness of 0.7 μm in this example.

The n-side guide layer 16 is formed of, for example, i-In_{0.49}Ga_{0.51}P, and has a thickness of 600 nm in this example.

The n-side enhanced layer 102 is formed of i-GaAs_{0.88}P_{0.12}, and has a thickness “d” smaller than a thickness “t” of the active layer 18 (“t”>“d”). The n-side enhanced layer 102 is equivalent to the n-side first barrier layer 56 in the second embodiment. In the present fourth embodiment, the thickness “d” of the n-side enhanced layer 102 is limited to a less value than the thickness “t” of the active layer 18. Hereinafter, the n-side enhanced layer 102 is referred to simply as the “enhanced layer.”The active layer 18 is formed of, for example, i-In_{0.07}Ga_{0.93}As, and has a thickness of 8 or 12 μm in this example.

The p-side enhanced layer 104, as with the n-side enhanced layer 102, is formed of i-GaAs_{0.88}P_{0.12}, and has a thickness “d” smaller than a thickness “t” of the active layer 18 (“t”>“d”).

The p-side guide layer 20 is formed of, for example, i-In_{0.49}Ga_{0.51}P, and has a thickness of 600 nm in this example.

The p-type cladding layer 22 is formed of, for example, p-(Al_{0.3}Ga_{0.7})_{0.5}In_{0.5}P, and has a thickness of 0.7 μm in this example.

The present embodiment assumes that when the thickness “t” of the active layer is 8 nm, the thicknesses “d” of the n-side enhanced layer 102 and the p-side enhanced layer 104 are 1 nm, 2 nm, 5 nm, or 7 nm, and that when the thickness “t” of the active layer is 12 nm, the thicknesses “d” are 1 nm, 2 nm, 5 nm, 7 nm, or 10 nm.

FIG. 33 is a schematic diagram showing a conduction band structure in neighborhood of the active layer in the semiconductor laser according to one embodiment of the present invention.

In FIG. 33, the n-side enhanced layer 102 and the p-side enhanced layer 104 have a bandgap energy whose level is somewhere in between bandgap energy levels of the active layer 18 and the n-side guide layer 16 or the p-side guide layer 20.

In addition, materials of the active layer 18, of the n-side guide layer 16 or the p-side guide layer 20, and of the n-side enhanced layer 102 or the p-side enhanced layer 104, are selected so that a refractive index of the n-side enhanced layer 102 or of the p-side enhanced layer 104 is somewhere in between a refractive index of the active layer 18 and that of the n-side guide layer 16 or of the p-side guide layer 20.

Next, a description will be given of threshold carrier density dependence, and quasi-Fermi level dependence, upon the thicknesses of the enhanced layers in the present embodiment.

In FIG. 33, ΔEc indicates a conduction band offset between the active layer 18 and the n-side guide layer 16 or of the p-side guide layer 20. Also, a dashed line (A) indicates a laser light emission conduction band quasi-Fermi level. A position of this quasi-Fermi level is shown as xΔEc, a product of ΔEc and a position coefficient “x”. In this case, the position coefficient “x” is in a 0<x<1 relationship.

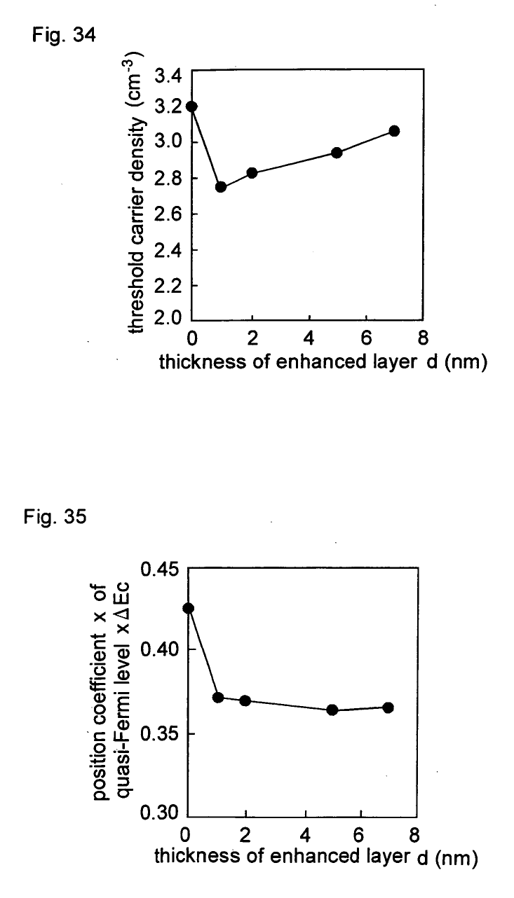

FIG. 34 is a graph showing the dependence of threshold carrier density on the thicknesses of the enhanced layers in the semiconductor laser according to one embodiment of the present invention. FIG. 35 is a graph that shows dependence of the quasi-Fermi level's position coefficient “x” upon the thicknesses of the enhanced layers in the semiconductor laser according to one embodiment of the present invention.

As with the calculation results showing the relationship between the threshold carrier density and quantum-well layer thickness of the semiconductor laser of FIG. 5, the simulation results shown in FIGS. 34 and 35 are based on the density matrix method described in the foregoing writing by M. Asada et al. Also, these simulation results are based on the assumption that the active layer 18 is 8 nm thick.

First in FIG. 34, when the n-side enhanced layer 102 and the p-side enhanced layer 104 are absent (“d”=0), threshold carrier density is 3.20 cm⁻³, whereas, when both the n-side enhanced layer 102 and the p-side enhanced layer 104 are present and the thicknesses of these layers are changed to 1 nm, 2 nm, 5 nm, and 7 nm, in that order, the threshold carrier density changes to 2.75 cm⁻³, 2.83 cm⁻³, 2.94 cm⁻³, and 3.06 cm⁻³, respectively. The threshold carrier density, therefore, can be reduced by providing the n-side enhanced layer 102 and p-side enhanced layer 104 that are thinner than the active layer.

Since the threshold carrier density is required for laser light emission, the fact that the threshold carrier density can be reduced indicates that the semiconductor laser can be reduced in threshold current.

Next in FIG. 35, when the n-side enhanced layer 102 and the p-side enhanced layer 104 are absent (“d”=0), the conduction band quasi-Fermi level obtainable is 0.424ΔEc, whereas, when the n-side enhanced layer 102 and the p-side enhanced layer 104 are present and the respective thicknesses are changed to 1 nm, 2 nm, 5 nm, and 7 nm, in that order, the conduction band quasi-Fermi level changes to 0.371ΔEc, 0.369ΔEc, 0.364ΔEc, and 0.365ΔEc, respectively. The conduction band quasi-Fermi level, therefore, can be reduced by providing the n-side enhanced layer 102 and p-side enhanced layer 104 that are thinner than the active layer.

The quasi-Fermi level is an index that indicates an average energy level of carrier injection into the active layer. The fact that the quasi-Fermi level is low means a low operating voltage and significant differences in energy level with respect to the n-side guide layer 16 and the p-side guide layer 20, and indicates that carriers do not easily overflow these guide layers. This, in turn, reduces the operating voltage and maintains appropriate high-temperature characteristics.

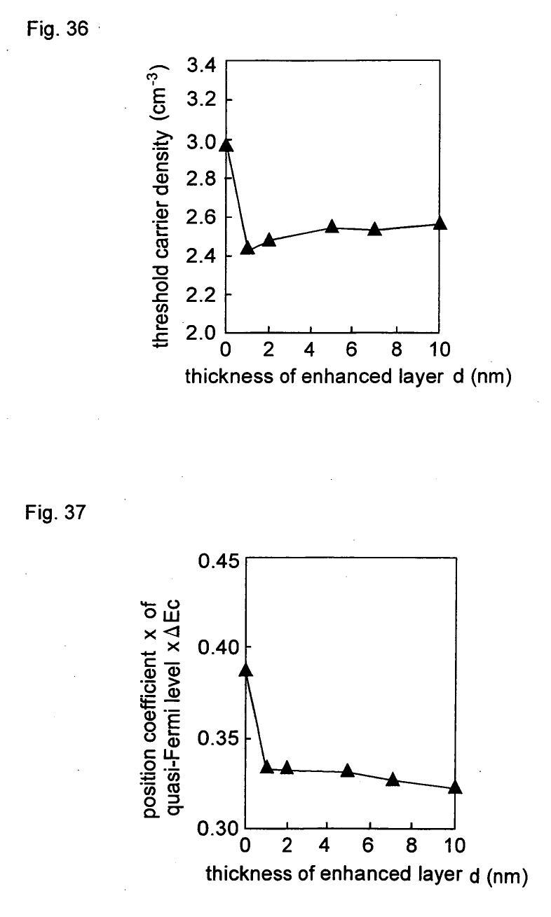

FIG. 36 is another graph that shows the dependence of the threshold carrier density upon the thicknesses of the enhanced layers in the semiconductor laser according to one embodiment of the present invention. FIG. 37 is another graph that shows the dependence of the quasi-Fermi level's position coefficient “x” upon the thicknesses of the enhanced layers in the semiconductor laser according to one embodiment of the present invention.

The simulation results shown in FIGS. 36 and 37 are based on the assumption that the active layer 18 is 12 nm. Also, the simulation results were obtained using the same simulation method of FIGS. 34 and 35.

First in FIG. 36, when the n-side enhanced layer 102 and the p-side enhanced layer 104 are absent (“d”=0), the threshold carrier density is 2.97 cm⁻³, whereas, when both the n-side enhanced layer 102 and the p-side enhanced layer 104 are present and the thicknesses of these layers are changed to 1 nm, 2 nm, 5 nm, 7 nm, and 10 nm, in that order, the threshold carrier density changes to 2.43 cm⁻³, 2.48 cm⁻³, 2.55 cm⁻³, 2.54 cm⁻³, and 2.56 cm⁻³, respectively. Providing the n-side enhanced layer 102 and p-side enhanced layer 104 that are thinner than the active layer, therefore, enables the threshold carrier density to be reduced, which, in turn, indicates that the semiconductor laser can be reduced in threshold current.

Next in FIG. 37, when the n-side enhanced layer 102 and the p-side enhanced layer 104 are absent (“d”=0), the conduction band quasi-Fermi level obtainable is 0.386ΔEc, whereas, when the n-side enhanced layer 102 and the p-side enhanced layer 104 are present and the respective thicknesses are changed to 1 nm, 2 nm, 5 nm, and 7 nm, and 10 nm, in that order, the conduction band quasi-Fermi level changes to 0.332ΔEc, 0.332ΔEc, 0.331ΔEc, and 0.327ΔEc, 0.323ΔEc, respectively. Providing the n-side enhanced layer 102 and p-side enhanced layer 104 that are thinner than the active layer, therefore, enables the conduction band quasi-Fermi level to be reduced, which, in turn, indicates that the semiconductor laser maintains a low operating voltage and appropriate high-temperature characteristics.

Next, effects of the enhanced layers will be described using an internal band structure of the active layer.

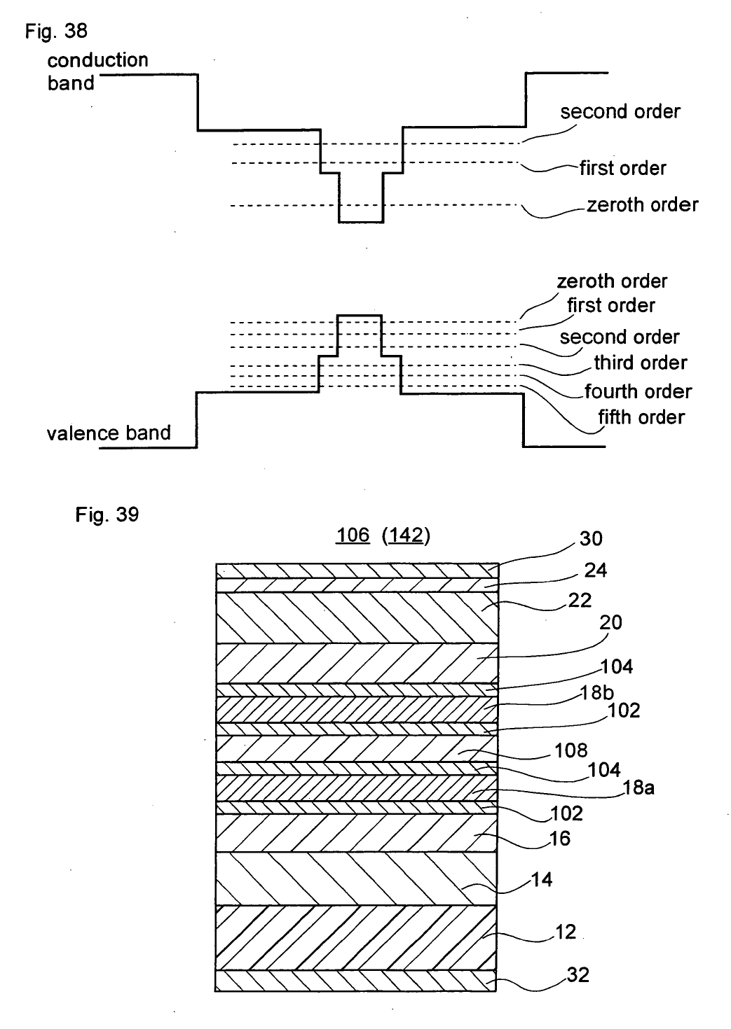

FIG. 38 is a schematic diagram showing a band structure in the neighborhood of the active layer in the semiconductor laser according to one embodiment of the present invention.

FIG. 38 indicates energy levels in the band structure neighboring the active layer 18, based on the assumption that the active layer 18 is 8 nm thick and that the n-side enhanced layer 102 and the p-side enhanced layer 104 are both 1 nm thick.

For a conduction band, three quantum states exist in the regions including the active layer 18, the n-side enhanced layer 102, and the p-side enhanced layer 104, and as far as the regions of the n-side enhanced layer 102 and the p-side enhanced layer 104 are concerned, two quantum states exist (first-order and second-order).

For a valence band, six quantum states exist in the regions including the active layer 18, the n-side enhanced layer 102, and the p-side enhanced layer 104, and as far as the regions of the n-side enhanced layer 102 and the p-side enhanced layer 104 are concerned, three quantum states exist (third-order, fourth-order, and fifth-order). That the valence band is larger in the number of quantum states is mainly due to the fact that holes have an effective mass greater than that of electrons.

Detailed analyses on emission states indicate that a quantum level of a zeroth order produces the gain required for emission. Also, first-order and higher-order quantum states act to store carriers, inclusive of electrons and holes.

That is to say, a significant effect of carrier density and quasi-Fermi level reduction by the enhanced layers can be obtained, provided that the conduction band and the valence band have a zeroth-order quantum level in respective band offsets between the active layer and the enhanced layers (n-side and p-side enhanced layers) and that two or more quantum levels exist in the regions including the active layer and the enhanced layers.

Because of their higher refractive indices than the guide layers, the enhanced layers have the effect of increasing a confinement ratio of light in the active layer. Therefore, even if a zeroth-order quantum level is absent in the band offsets between the active layer and the enhanced layers or even if two or more quantum levels are absent in the regions including the active layer and the enhanced layers, the enhanced layers have the effect of reducing the threshold carrier density and the quasi-Fermi level to a certain extent.

Since the quasi-Fermi levels in the valence band are originally low, only the effect of reduction in the quasi-Fermi levels of the conduction band has been described in the present embodiment. In the valence band, quasi-Fermi levels also decrease similarly. As the case may be, the quasi-Fermi levels in the valence band increase above those of the conduction band, in which case, decreases in the quasi-Fermi levels of the valence band become effective.

While examples of 8-nm and 12-nm active layer thicknesses have been described in the present embodiment, the thickness of the active layer is not limited to these values and it was confirmed that equivalent effects can likewise be obtained by disposing an active layer of any other appropriate thickness.

The semiconductor laser 100 in the present embodiment can be reduced in threshold carrier density and in quasi-Fermi level if the enhanced layers 102, 104 that are thinner than an active layer 18 and somewhere in between the active layer 18 and guide layers 16, 20 in terms of both bandgap energy level and refractive index, are provided adjacently to the active layer 18. The above, in turn, enables construction of a semiconductor laser having a small threshold current, a low operating voltage, and appropriate high-temperature characteristics.

Thirteenth Variation

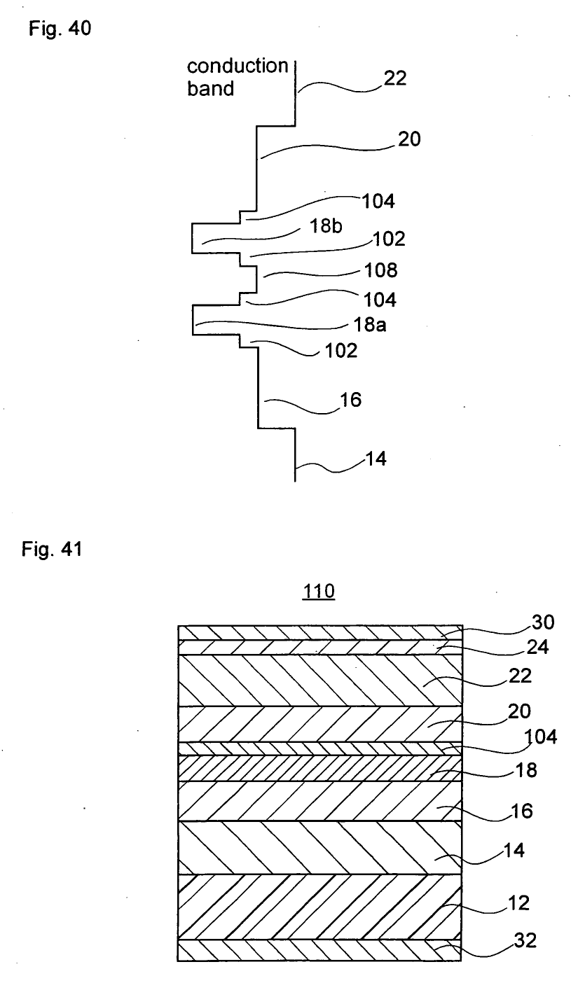

FIG. 39 is a sectional view of a variation of the semiconductor laser according to one embodiment of the present invention. FIG. 40 is a schematic diagram showing a structure of a conduction band in neighborhood of active layers in the semiconductor laser of FIG. 39.

Semiconductor laser 106 in FIG. 39 is of a double-quantum-well (DQW) structure with two active layers. In the DQW structure, a first active layer 18a and a second active layer 18b are each disposed between respective enhanced layer pairs each consisting of one n-side enhanced layer 102 and one p-side enhanced layer 104. A barrier layer 108 is disposed between the p-side enhanced layer 104 disposed adjacently to the first active layer 18a, and the n-side enhanced layer 102 disposed adjacently to the second active layer 18b. Other structural aspects are the same for the semiconductor laser 100.

In this variation, an n-side guide layer 16 and a p-side guide layer 20 are formed of i-In_{0.49}Ga_{0.51}P and have a thickness of 600 nm.

The n-side enhanced layers 102 and p-side enhanced layers 104 disposed adjacently to the active layers 18a and 18b are each 10 nm thick and formed of i-GaAs_{0.88}P_{0.12}.

The first active layer 18a and the second active layer 18b are both 12 nm thick and formed of In_{0.07}Ga_{0.93}As. The n-side enhanced layers 102 and the p-side enhanced layers 104 are thinner than the active layers 18a and 18b that are adjacent to the enhanced layers 102 and 104.

The barrier layer 108 is 20 nm thick and formed of i-In_{0.49}Ga_{0.51}P, the same constituent material as used for the n-side guide layer 16 and the p-side guide layer 20.

As shown in FIG. 38, the n-side enhanced layers 102 and the p-side enhanced layers 104 are constructed of a material whose bandgap energy level is somewhere in between a bandgap energy level of the adjacent first active layer 18a or second active layer 18b and a bandgap energy level of the adjacent n-side guide layer 16 or p-side guide layer 20 or of the barrier layer 108.

The semiconductor laser 106 of this variation also has advantageous effects equivalent to those of the foregoing semiconductor laser 100.

Fourteenth Variation

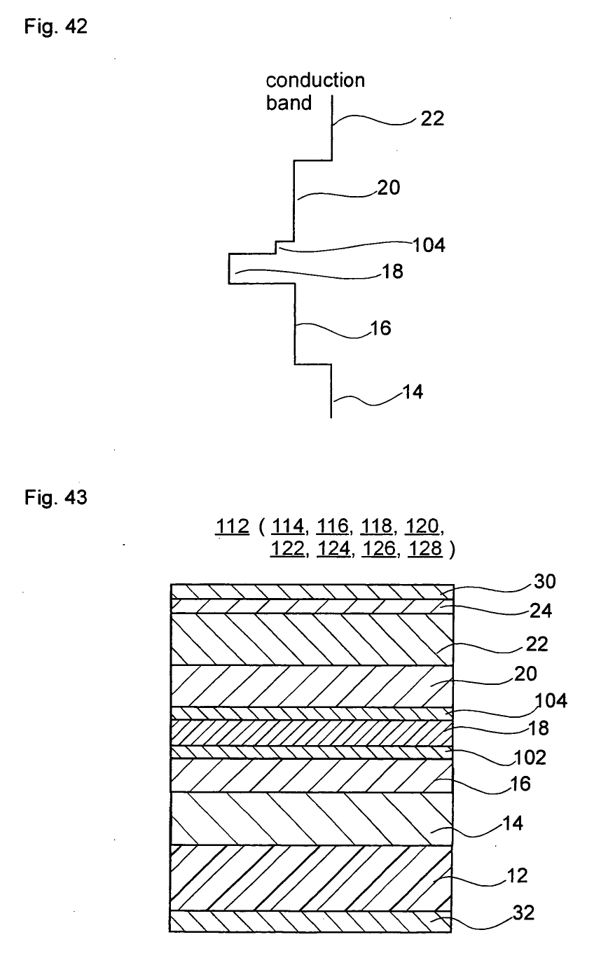

FIG. 41 is a sectional view of a variation of the semiconductor laser according to one embodiment of the present invention. FIG. 42 is a schematic diagram showing a structure of a conduction band in neighborhood of an active layer in the semiconductor laser of FIG. 41.

In semiconductor laser 110 in FIG. 41, only a p-side enhanced layer 104 is disposed adjacently to an active layer 18, and an n-side enhanced layer is not disposed.

In this variation, an n-side guide layer 16 and a p-side guide layer 20 are formed of i-In_{0.49}Ga_{0.51}P and have a thickness of 600 nm. The p-side enhanced layer 104 is 10 nm thick and formed of i-GaAs_{0.88}P_{0.12}. The active layer 18 has a 12-nm layer thickness and is formed of In_{0.07}Ga_{0.93}As.

The p-side enhanced layer 104 is thinner than the active layer 18. Also, the p-side enhanced layer 104 with a higher refractive index than the p-side guide layer 20 enhances a confinement ratio of light in the active layer 18. In addition, the p-side enhanced layer 104 is constructed of a material whose bandgap energy level is somewhere in between a bandgap energy level of the active layer 18 and that of the p-side guide layer 20 disposed adjacently to the p-side enhanced layer 104.

Hence, this variation has advantageous effects such as reducing a quasi-Fermi level by storing a larger quantity of carriers without degrading the gain obtained at a zeroth-order level, and these effects are comparable to those obtainable when an enhanced layer is disposed adjacently to both sides of the active layer. While this variation has an enhanced layer at a p-side, equivalent effects can likewise be obtained by disposing the enhanced layer at an n-side.

Fifteenth Variation

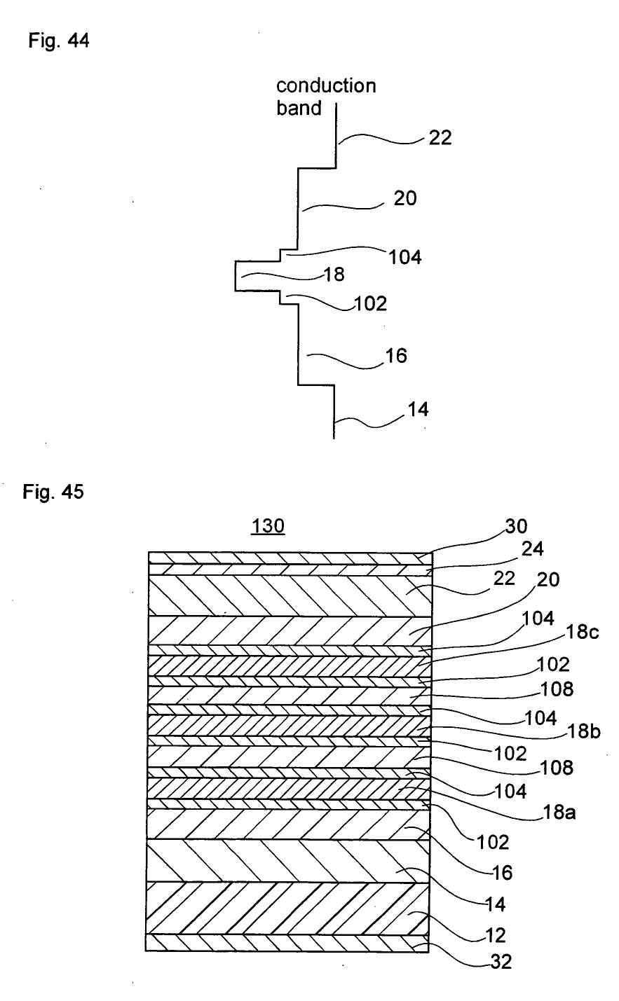

FIG. 43 is a sectional view of a variation of the semiconductor laser according to one embodiment of the present invention. FIG. 44 is a schematic diagram showing a structure of a conduction band in neighborhood of an active layer in the semiconductor laser of FIG. 43.

In FIGS. 43 and 44, semiconductor laser 112 of this variation has an emission wavelength of about 870 nm and is basically the same as the semiconductor laser 100 in terms of configuration. However, the semiconductor laser 112 differs in the kinds of materials used in a layer structure, except for an n-GaAs substrate 12 and a contact layer 24.

More specifically, an n-type cladding layer 14 and a p-type cladding layer 22 are formed of n-Al_{0.4}Ga_{0.6}As and p-Al₀Ga_{0.6}As, respectively, and have a thickness of 1.5 μm.

An n-side guide layer 16 and a p-side guide layer 20 are formed of i-Al_{0.3}Ga_{0.7}As and have a thickness of 350 nm.

An n-side enhanced layer 102 and a p-side enhanced layer 104 are formed of i-Al_{0.2}Ga_{0.8}As and have a thickness of 5 nm.

An active layer 18 is formed of i-GaAs and has a thickness of 12 nm.

The semiconductor laser 112 is of a GaAs single-quantum-well structure with a layer thickness of 12 nm, and uses 5-nm-thick i-Al_{0.2}Ga_{0.8}As enhanced layers. For AlGaAs, an increase in Al-content ratio not only increases bandgap energy, but also reduces a refractive index, so the enhanced layers have a refractive index that is somewhere in between those of the active layer and the guide layers. Bandgap energy also takes a value that is somewhere in between bandgap energy levels of the active layer and the guide layers.

While this variation has an enhanced layer at both sides of the active layer in a single quantum well, equivalent effects can likewise be obtained by disposing the enhanced layer only at one side of the active layer, or of active layers in multiple quantum wells.

The semiconductor laser 112 of this variation also has advantageous effects equivalent to those of the foregoing semiconductor laser 100.

Sixteenth Variation

A semiconductor laser 114 of this variation has an emission wavelength of about 808 nm and is basically the same as the semiconductor laser 100 in terms of configuration. However, the semiconductor laser 114 differs in the kinds of materials used in a layer structure, except for an n-GaAs substrate 12 and a contact layer 24. Sectional views of the semiconductor laser 114 and of the semiconductor lasers 116, 118, 120, 122, 124, 126, and 128 described later herein, and schematic diagrams that show respective conduction band structures are the same as those shown in FIGS. 43 and 44, respectively.

In the semiconductor laser 114, an n-type cladding layer 14 and a p-type cladding layer 22 are formed of n-Al_{0.5}Ga_{0.5}As and p-Al_{0.5}Ga_{0.5}As, respectively, and have a thickness of 1.5 μm.

An n-side guide layer 16 and a p-side guide layer 20 are formed of i-Al_{0.4}Ga_{0.6}As and have a thickness of 350 nm.

An n-side enhanced layer 102 and a p-side enhanced layer 104 are formed of i-Al_{0.3}Ga_{0.7}As and have a thickness of 5 nm.

An active layer 18 is formed of i-Al_{0.1}Ga_{0.9}As and has a thickness of 12 nm.

The 12-nm-thick active layer in the semiconductor laser 114 is of an AlGaAs single-quantum-well structure with an Al-content ratio of 0.1, and the 5-nm-thick enhanced layers are AlGaAs layers with an Al-content ratio of 0.3.

Since the active layer uses AlGaAs, the guide layers and the cladding layers have respective Al-content ratios increased above those of the semiconductor laser 112 of the fifteenth variation in order to ensure differences in refractive index and in energy gap.

The semiconductor laser 114 of this variation also has advantageous effects equivalent to those of the foregoing semiconductor laser 100.

Seventeenth Variation

A semiconductor laser 116 of this variation has an emission wavelength of about 808 nm and is basically the same as the semiconductor laser 100 in terms of configuration. However, the semiconductor laser 116 differs in the kinds of materials used in a layer structure, except for an n-GaAs substrate 12 and a contact layer 24.

More specifically, an n-type cladding layer 14 and a p-type cladding layer 22 are formed of n-Al_{0.7}Ga_{0.3}As and p-Al_{0.7}Ga_{0.3}As, respectively, and have a thickness of 1.5 μm.

An n-side guide layer 16 and a p-side guide layer 20 are formed of i-In_{0.49}Ga_{0.51}P and have a thickness of 100 nm.

An n-side enhanced layer 102 and a p-side enhanced layer 104 are formed of i-GaAs_{0.78}P_{0.22} and have a thickness of 5 nm.

An active layer 18 is formed of i-In_{0.13}Ga_{0.87}As_{0.75}P_{0.25} and has a thickness of 10 nm.

The 10-nm-thick i-In_{0.13}Ga_{0.87}As_{0.75}P_{0.25} active layer in the semiconductor laser 116 is of a single-quantum-well structure, and 5-nm-thick i-GaAs_{0.78}P_{0.12} AlGaAs layers are used as the enhanced layers. The i-In_{0.49}Ga_{0.51}P guide layers realize an essentially Al-free structure in which neither the active layer, the enhanced layers, nor the guide layers contain Al. The Al_{0.7}Ga_{0.3}As cladding layers are constructed to be smaller than the guide layers in refractive index and thus to confine light in the guide layer.

The semiconductor laser 116 of this variation also has advantageous effects equivalent to those of the foregoing semiconductor laser 100.

Eighteenth Variation

A semiconductor laser 118 of this variation has an emission wavelength of about 808 nm and is basically the same as the semiconductor laser 100 in terms of configuration. However, the semiconductor laser 118 differs in the kinds of materials used in a layer structure, except for an n-GaAs substrate 12 and a contact layer 24.

More specifically, an n-type cladding layer 14 and a p-type cladding layer 22 are formed of n-Al_{0.7}Ga_{0.3}As and p-Al_{0.7}Ga_{0.3}As, respectively, and have a thickness of 1.5 μm.

An n-side guide layer 16 and a p-side guide layer 20 are formed of i-In_{0.49}Ga_{0.51}P and have a thickness of 100 nm.

An n-side enhanced layer 102 and a p-side enhanced layer 104 are formed of i-In_{0.37}Ga_{0.63}As_{0.30}P_{0.70} and have a thickness of 5 nm.

An active layer 18 is formed of i-In_{0.13}Ga_{0.87}As_{0.75}P_{0.25} and has a thickness of 10 nm.

The 10-nm-thick i-In_{0.13}Ga_{0.87}As_{0.75}P_{0.25} active layer in the semiconductor laser 118 is of a single-quantum-well structure, and 5-nm-thick i-In_{0.37}Ga_{0.63}As_{0.30}P_{0.70} layers are used as the enhanced layers. The i-In_{0.49}Ga_{0.51}P guide layers realize an essentially Al-free structure in which neither the active layer, the enhanced layers, nor the guide layers contain Al. The enhanced layers of InGaAsP have an As-content ratio and a Ga-content ratio so as to be lattice-matched to the GaAs substrate.

The semiconductor laser 118 of this variation also has advantageous effects equivalent to those of the foregoing semiconductor laser 100.

Nineteenth Variation

A semiconductor laser 120 of this variation has an emission wavelength of about 808 nm and is basically the same as the semiconductor laser 100 in terms of configuration. However, the semiconductor laser 120 differs in the kinds of materials used in a layer structure, except for an n-GaAs substrate 12 and a contact layer 24.

More specifically, an n-type cladding layer 14 and a p-type cladding layer 22 are formed of n-(Al_{0.30}Ga_{0.70})_{0.5}In_{0.5}P and p-(Al_{0.30}Ga_{0.70})₀₀₅In_{0.5}P, respectively, and have a thickness of 1.5 μm.

An n-side guide layer 16 and a p-side guide layer 20 are formed of i-Al_{0.4}Ga_{0.6}As and have a thickness of 350 nm.

An n-side enhanced layer 102 and a p-side enhanced layer 104 are formed of i-Al_{0.3}Ga_{0.7}As and have a thickness of 5 nm.

An active layer 18 is formed of i-Al_{0.10}Ga_{0.90}As and has a thickness of 12 nm.

The 12-nm-thick i-Al_{0.10}Ga_{0.90}As active layer in the semiconductor laser 118 is of a single-quantum-well structure.

The semiconductor laser 120 of this variation also has advantageous effects equivalent to those of the foregoing semiconductor laser 100.

Twentieth Variation

A semiconductor laser 122 of this variation has an emission wavelength of about 808 nm and is basically the same as the semiconductor laser 100 in terms of configuration. However, the semiconductor laser 122 differs in the kinds of materials used in a layer structure, except for an n-GaAs substrate 12 and a contact layer 24.

More specifically, an n-type cladding layer 14 and a p-type cladding layer 22 are formed of n-(Al_{0.30}Ga_{0.70})_{0.5}In_{0.5}P and p-(Al_{0.30}Ga_{0.70})_{0.5}In_{0.5}P, respectively, and have a thickness of 1.5 μm.

An n-side guide layer 16 and a p-side guide layer 20 are formed of i-Al_{0.49}Ga_{0.51}P and have a thickness of 100 nm.

An n-side enhanced layer 102 and a p-side enhanced layer 104 are formed of i-GaAs_{0.78}P_{0.22} and have a thickness of 5 nm.

An active layer 18 is formed of i-In_{0.13}Ga_{0.87}As_{0.75}P_{0.25} and has a thickness of 10 nm.

The 10-nm-thick i-In_{0.13}Ga_{0.87}As_{0.75}P_{0.25} active layer in the semiconductor laser 122 is of a single-quantum-well structure.

The semiconductor laser 122 of this variation also has advantageous effects equivalent to those of the foregoing semiconductor laser 100.

Twenty-First Variation

A semiconductor laser 124 of this variation has an emission wavelength of about 808 nm and is basically the same as the semiconductor laser 100 in terms of configuration. However, the semiconductor laser 124 differs in the kinds of materials used in a layer structure, except for an n-GaAs substrate 12 and a contact layer 24.

More specifically, an n-type cladding layer 14 and a p-type cladding layer 22 are formed of n-(Al_{0.30}Ga_{0.70})_{0.5}In_{0.5}P and p-(Al_{0.30}Ga_{0.70})_{0.5}In_{0.5}P, respectively, and have a thickness of 1.5 μm.

An n-side guide layer 16 and a p-side guide layer 20 are formed of i-In_{0.49}Ga_{0.51}P and have a thickness of 100 nm.

An n-side enhanced layer 102 and a p-side enhanced layer 104 are formed of i-In_{0.37}Ga_{0.63}As_{0.30}P_{0.70} and have a thickness of 5 nm.

An active layer 18 is formed of i-In_{0.13}Ga_{0.87}As_{0.75}P_{0.25} and has a thickness of 10 nm.

The 10-nm-thick i-In_{0.13}Ga_{0.87}As_{0.75}P_{0.25} active layer in the semiconductor laser 124 is of a single-quantum-well structure. The enhanced layers of InGaAsP have an As-content ratio and a Ga-content ratio so as to be lattice-matched to the GaAs substrate.

The semiconductor laser 124 of this variation also has advantageous effects equivalent to those of the foregoing semiconductor laser 100.

Twenty-Second Variation

A semiconductor laser 126 of this variation has an emission wavelength of about 808 nm and is basically the same as the semiconductor laser 100 in terms of configuration. However, the semiconductor laser 126 differs in the kinds of materials used in a layer structure, except for an n-GaAs substrate 12 and a contact layer 24.

More specifically, an n-type cladding layer 14 and a p-type cladding layer 22 are formed of n-(Al_{0.30}Ga_{0.70})_{0.5}In_{0.5}P and p-(Al_{0.30}Ga_{0.70})_{0.5}In_{0.5}P, respectively, and have a thickness of 0.7 μm.

An n-side guide layer 16 and a p-side guide layer 20 are formed of i-In_{0.49}Ga_{0.51}P and have a thickness of 500 nm.

An n-side enhanced layer 102 and a p-side enhanced layer 104 are formed of i-In_{0.37}Ga_{0.63}As_{0.30}P_{0.70} and have a thickness of 5 nm.

An active layer 18 is formed of i-GaAs_{0.88}P_{0.12} and has a thickness of 12 nm.

The 12-nm-thick i-GaAs_{0.88}P_{0.12} active layer in the semiconductor laser 126 is of a single-quantum-well structure. The enhanced layers of InGaAsP have an As-content ratio and a Ga-content ratio so as to be lattice-matched to the GaAs substrate.

The semiconductor laser 126 of this variation also has advantageous effects equivalent to those of the foregoing semiconductor laser 100.

Twenty-Third Variation

A semiconductor laser 128 of this variation has an emission wavelength of about 808 nm and is basically the same as the semiconductor laser 100 in terms of configuration. However, the semiconductor laser 126 differs in the kinds of materials used in a layer structure, except for an n-GaAs substrate 12 and a contact layer 24.

More specifically, an n-type cladding layer 14 and a p-type cladding layer 22 are formed of n-(Al_{0.30}Ga_{0.70})_{0.5}In_{0.5}p and p-(Al_{0.30}Ga_{0.70})_{0.5}In_{0.5}P, respectively, and have a thickness of 0.7 μm.

An n-side guide layer 16 and a p-side guide layer 20 are formed of i-In_{0.49}Ga_{0.51}P and have a thickness of 500 nm.

An n-side enhanced layer 102 and a p-side enhanced layer 104 are formed of i-GaAs_{0.78}P_{0.22} and have a thickness of 2 nm.

An active layer 18 is formed of i-GaAs_{0.88}P_{0.12} and has a thickness of 12 nm.

The 12-nm-thick i-GaAs_{0.88}P_{0.12} active layer in the semiconductor laser 128 is of a single-quantum-well structure.

The semiconductor laser 128 of this variation also has advantageous effects equivalent to those of the foregoing semiconductor laser 100.

Twenty-Fourth Variation

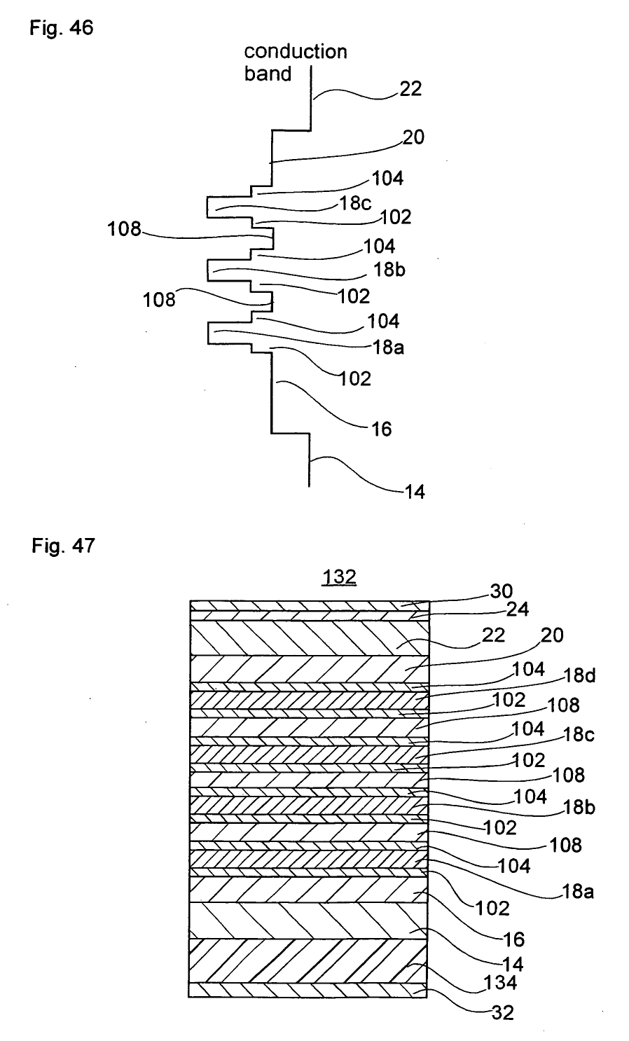

FIG. 45 is a sectional view of a variation of the semiconductor laser according to one embodiment of the present invention. FIG. 46 is a schematic diagram showing a structure of a conduction band in neighborhood of active layers in the semiconductor laser of FIG. 45.

Semiconductor laser 130 in FIG. 45 is of a triple-quantum-well structure with three active layers, and has an emission wavelength of 660 nm.

In this structure of the semiconductor laser 130, a first active layer 18a, a second active layer 18b, and a third active layer 18c are each sandwiched between respective enhanced layer pairs each consisting of one n-side enhanced layer 102 and one p-side enhanced layer 104.

Also, a barrier layer 108 is disposed between the p-side enhanced layer 104 disposed adjacently to the first active layer 18a, and the n-side enhanced layer 102 disposed adjacently to the second active layer 18b, and another barrier layer 108 is disposed between the p-side enhanced layer 104 disposed adjacently to the second active layer 18b, and the n-side enhanced layer 102 disposed adjacently to the third active layer 18c. Other structural aspects are the same for the semiconductor laser 100.

In this variation, an n-type cladding layer 14 and a p-type cladding layer 22 are formed of n-(Al_{0.70}Ga_{0.30})_{0.5}In_{0.5}p and p-(Al_{0.70}Ga_{0.30})_{0.5}In_{0.5}p, respectively, and have a thickness of 1.3 μm.

An n-side guide layer 16 and a p-side guide layer 20 are formed of i-(Al_{0.45}Ga_{0.55})_{0.5}In_{0.5}P, and have a thickness of 5 nm.

The n-side enhanced layers 102 and p-side enhanced layers 104 disposed adjacently to the respective active layers are 2 nm thick and formed of i-(Al_{0.35}Ga_{0.65})_{0.5}In_{0.5}P.

The first active layer 18a, the second active layer 18b, and the third active layer 18c are each 8 nm thick and formed of In_{0.56}Ga_{0.44}P. The n-side enhanced layers 102 and the p-side enhanced layers 104 are each thinner than the active layer 18a, 18b, or 18c that is adjacent to the enhanced layer.

The barrier layers 108 are 5 nm thick and formed of i-(Al_{0.45}Ga_{0.55})_{0.5}In_{0.5}P, the same constituent material as used for the n-side guide layer 16 and the p-side guide layer 20.

As shown in FIG. 46, the n-side enhanced layers 102 and the p-side enhanced layers 104 are constructed of a material whose bandgap energy level is somewhere in between a bandgap energy level of the adjacent first active layer 18a, second active layer 18b, or third active layer 18c, and a bandgap energy level of the adjacent n-side guide layer 16, p-side guide layer 20, or barrier layer 108.

The semiconductor laser 130 of this variation also has advantageous effects equivalent to those of the foregoing semiconductor laser 100.

The enhanced layers in this variation are disposed with reference to the semiconductor laser described in M. Mannoh, J. Hoshina, S. Kamiyama, H. Ohta, Y. Ban, and K. Ohnaka, “High-power and high-temperature operation of GaInP/AlGaInP strained multiple quantum well lasers,” Appl. Phys. Lett., Vol. 62, No. 11, pp. 1173-1175, 1993.

Twenty-Fifth Variation

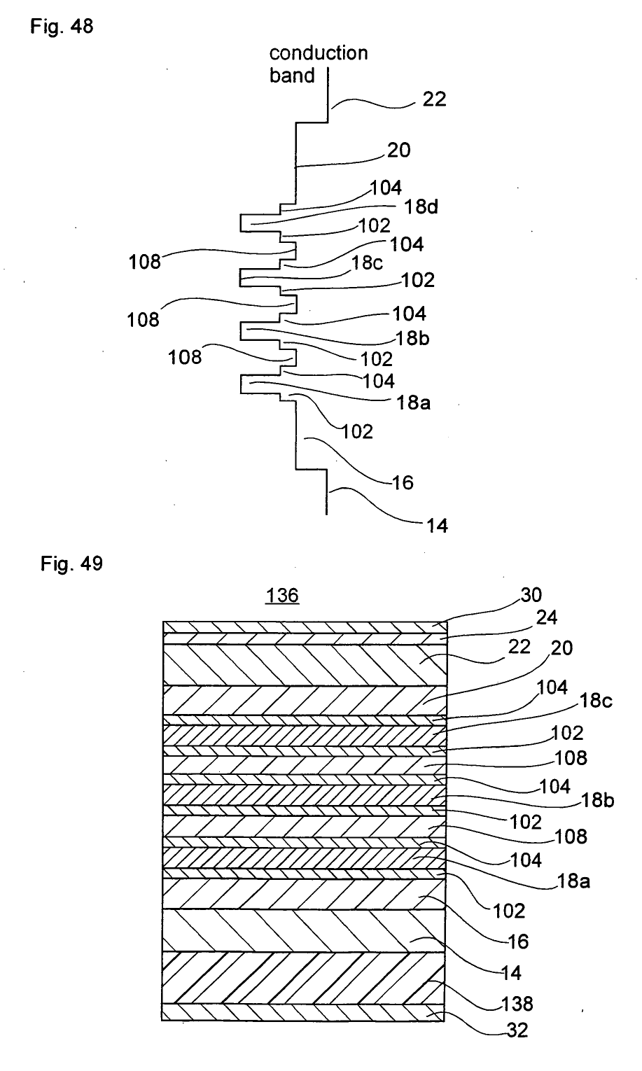

FIG. 47 is a sectional view of a variation of the semiconductor laser according to one embodiment of the present invention. FIG. 48 is a schematic diagram showing a structure of a conduction band in neighborhood of active layers in the semiconductor laser of FIG. 47.

Semiconductor laser 132 in FIG. 47 is of a quadruple-quantum-well structure with four active layers, and has an emission wavelength of 400 nm.

The semiconductor laser 132 has an n-type cladding layer 14 and an n-side guide layer 16 disposed in that order on an n-GaN semiconductor substrate 134. Also, a p-side guide layer 20 and a p-type cladding layer 22 are disposed in that order via four active layers 18, and a p-GaN contact layer 24 is disposed on the p-type cladding layer 22.

Each of the four active layers 18, namely, a first active layer 18a, a second active layer 18b, a third active layer 18c, and a fourth active layer 18d, is sandwiched between respective enhanced layer pairs each consisting of one n-side enhanced layer 102 and one p-side enhanced layer 104. A barrier layer 108 is disposed between the p-side enhanced layer 104 disposed adjacently to the first active layer 18a, and the n-side enhanced layer 102 disposed adjacently to the second active layer 18b. Another barrier layer 108 is disposed between the p-side enhanced layer 104 disposed adjacently to the second active layer 18b, and the n-side enhanced layer 102 disposed adjacently to the third active layer 18c. Yet another barrier layer 108 is disposed between the p-side enhanced layer 104 disposed adjacently to the third active layer 18c, and the n-side enhanced layer 102 disposed adjacently to the fourth active layer 18d. Other structural aspects are the same for the semiconductor laser 100.

In this variation, the n-type cladding layer 14 and the p-type cladding layer 22 are formed of n-Al_{0.14}Ga_{0.86}N and p-Al_{0.14}Ga_{0.86}N, respectively, and have a thickness of 0.5 μm.

The n-side guide layer 16 and the p-side guide layer 20 are formed of i-GaN and have a thickness of 100 nm.

The n-side enhanced layers 102 and the p-side enhanced layers 104 are formed of i-In_{0.05}Ga_{0.95}N and have a layer thickness of 1 nm.

The first active layer 18a, the second active layer 18b, the third active layer 18c, and the fourth active layer 18d are each 3.5 nm thick and formed of In_{0.05}Ga_{0.85}N.

The n-side enhanced layers 102 and the p-side enhanced layers-104 are each thinner than the active layer 18a, 18b, 18c, or 18d that is adjacent to the enhanced layer.

The barrier layers 108 are 7 nm thick and formed of the same i-GaN constituent material as used for the n-side guide layer 16 and the p-side guide layer 20.

As shown in FIG. 48, the n-side enhanced layers 102 and the p-side enhanced layers 104 are constructed of a material whose bandgap energy level is somewhere in between a bandgap energy level of the adjacent first active layer 18a, second active layer 18b, third active layer 18c, or fourth active layer 18d, and a bandgap energy level of the adjacent n-side guide layer 16, p-side guide layer 20, or barrier layer 108.

The semiconductor laser 132 of this variation also has advantageous effects equivalent to those of the foregoing semiconductor laser 100.

The enhanced layers in this variation are disposed with reference to the semiconductor laser described in P. G. Eliseev, G. A. Symolyakov, and M. Osinski, “Ghost modes and resonant effects in AlGaN—InGaN-GaN lasers,” IEEE J. Sel. Topics Quantum Electron., Vol. 5, No. 3, pp. 771-779, 1999.

Twenty-Sixth Variation

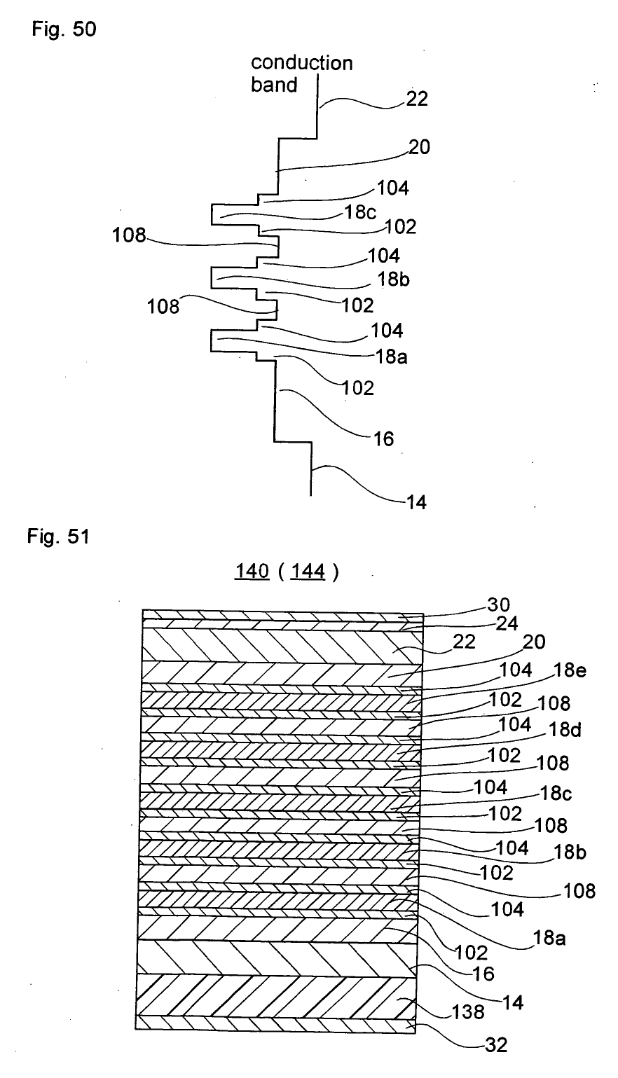

FIG. 49 is a sectional view of a variation of the semiconductor laser according to one embodiment of the present invention. FIG. 50 is a schematic diagram showing a structure of a conduction band in neighborhood of active layers in the semiconductor laser of FIG. 49.

Semiconductor laser 136 in FIG. 49 is of a triple-quantum-well structure with three active layers, and has an emission wavelength of 1,310 nm.

The semiconductor laser 136 has an n-type cladding layer 14 and an n-side guide layer disposed in that order on an n-InP semiconductor substrate 138. Also, a p-side guide layer 20 and a p-type cladding layer 22 are disposed in that order via three active layers 18, and a p-InP contact layer 24 is disposed on the p-type cladding layer 22.

Each of the three active layers 18, namely, a first active layer 18a, a second active layer 18b, and a third active layer 18c, is sandwiched between respective enhanced layer pairs each consisting of one n-side enhanced layer 102 and one p-side enhanced layer 104.

A barrier layer 108 is disposed between the p-side enhanced layer 104 disposed adjacently to the first active layer 18a, and the n-side enhanced layer 102 disposed adjacently to the second active layer 18b. Another barrier layer 108 is disposed between the p-side enhanced layer 104 disposed adjacently to the second active layer 18b, and the n-side enhanced layer 102 disposed adjacently to the third active layer 18c. Other structural aspects are the same for the semiconductor laser 100.

In this variation, the n-type cladding layer 14 and the p-type cladding layer 22 are formed of n-In_{0.817}Ga_{0.183}As_{0.40}P_{0.60} and p-In_{0.817}Ga_{0.183}As_{0.40}P_{0.60}, respectively, and have a thickness of 78.5 nm.

The n-side guide layer 16 and the p-side guide layer 20 are formed of i-In_{0.738}Ga_{0.262}As_{0.568}P_{0.432} and have a thickness of 50 nm.

The n-side enhanced layers 102 and p-side enhanced layers 104 located adjacently to the respective active layers are 4 nm thick and formed of i-In_{0.652}Ga_{0.348}As_{0.750}P_{0.250}.

The first active layer 18a, the second active layer 18b, and the third active layer 18c are each 7.5 nm thick and formed of i-In_{0.557}Ga_{0.443}As_{0.950}P_{0.050}. The n-side enhanced layers 102 and the p-side enhanced layers 104 are each thinner than the active layer 18a, 18b, or 18c that is adjacent to the enhanced layer.

The barrier layers 108 are 23 nm thick and formed of i-In_{0.738}Ga_{0.262}As_{0.568}P_{0.432}, the same constituent material as used for the n-side guide layer 16 and the p-side guide layer 20.

As shown in FIG. 50, the n-side enhanced layers 102 and the p-side enhanced layers 104 are constructed of a material whose bandgap energy level is somewhere in between a bandgap energy level of the adjacent first active layer 18a, second active layer 18b, or third active layer 18c, and a bandgap energy level of the adjacent n-side guide layer 16, p-side guide layer 20, or barrier layer 108.

The semiconductor laser 136 of this variation also has advantageous effects equivalent to those of the foregoing semiconductor laser 100.

The enhanced layers in this variation are disposed with reference to the semiconductor laser described in Z. M. Li and T. Bradford, “A comparative study of temperature sensitivity of InGaAsP and AlGaAs MQW lasers using numerical simulations,” IEEE J. Quantum Electron., Vol. 31, No. 10, pp. 1841-1847, 1995.

Twenty-Seventh Variation

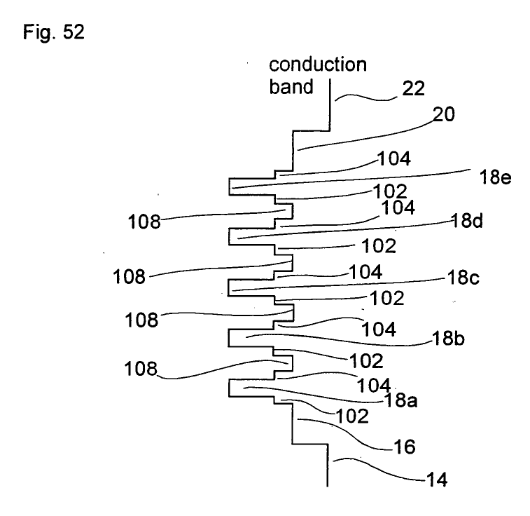

FIG. 51 is a sectional view of a variation of the semiconductor laser according to one embodiment of the present invention. FIG. 52 is a schematic diagram showing a structure of a conduction band in neighborhood of active layers in the semiconductor laser of FIG. 51.

Semiconductor laser 140 in FIG. 51 is of a quintuple-quantum-well structure with five active layers, and has an emission wavelength of 1,310 nm.

The semiconductor laser 140 has an n-type cladding layer 14 and an n-side guide layer disposed in that order on an n-InP semiconductor substrate 138. Also, a p-side guide layer 20 and a p-type cladding layer 22 are disposed in that order via five active layers 18, and a p-InP contact layer 24 is disposed on the p-type cladding layer 22.

Each of the five active layers 18, namely, a first active layer 18a, a second active layer 18b, a third active layer 18c, a fourth active layer 18d, and a fifth active layer 18e, is sandwiched between respective enhanced layer pairs each consisting of one n-side enhanced layer 102 and one p-side enhanced layer 104. A barrier layer 108 is disposed between the p-side enhanced layer 104 disposed adjacently to the first active layer 18a, and the n-side enhanced layer 102 disposed adjacently to the second active layer 18b. Another barrier layer 108 is disposed between the p-side enhanced layer 104 disposed adjacently to the second active layer 18b, and the n-side enhanced layer 102 disposed adjacently to the third active layer 18c. Yet another barrier layer 108 is disposed between the p-side enhanced layer 104 disposed adjacently to the third active layer 18c, and the n-side enhanced layer 102 disposed adjacently to the fourth active layer 18d. A further barrier layer 108 is disposed between the p-side enhanced layer 104 disposed adjacently to the fourth active layer 18d, and the n-side enhanced layer 102 disposed adjacently to the fifth active layer 18e. Other structural aspects are the same for the semiconductor laser 100.

In this variation, the n-type cladding layer 14 and the p-type cladding layer 22 are formed of n-Al_{0.47}Ga_{0.53}P and p-Al_{0.47}Ga_{0.53}P, respectively, and have a thickness of 0.2 μm.

The n-side guide layer 16 and the p-side guide layer 20 are formed of i-Al_{0.30}Ga_{0.17}In_{0.53}As and have a thickness of 200 nm.

The n-side enhanced layers 102 and p-side enhanced layers 104 located adjacently to the respective active layers are 2 nm thick and formed of i-Al_{0.22}Ga_{0.25}In_{0.53}As.

The first active layer 18a, the second active layer 18b, the third active layer 18c, the fourth active layer 18d, and the fifth active layer 18e are each 5 nm thick and formed of i-Al_{0.16}Ga_{0.31}In_{0.53}As. The n-side enhanced layers 102 and the p-side enhanced layers 104 are each thinner than the active layer 18a, 18b, 18c, 18d, or 18e that is adjacent to the enhanced layer.

The barrier layers 108 are 10 nm thick and formed of i-Al_{0.30}Ga_{0.17}In_{0.53}As, the same constituent material as used for the n-side guide layer 16 and the p-side guide layer 20.

As shown in FIG. 52, the n-side enhanced layers 102 and the p-side enhanced layers 104 are constructed of a material whose bandgap energy level is somewhere in between a bandgap energy level of the adjacent first active layer 18a, second active layer 18b, third active layer 18c, fourth active layer 18d, or fifth active layer 18e, and a bandgap energy level of the adjacent n-side guide layer 16, p-side guide layer 20, or barrier layer 108.

The semiconductor laser 140 of this variation also has advantageous effects equivalent to those of the foregoing semiconductor laser 100.

The enhanced layers in this variation are disposed with the p-type cladding layer 22.

Each of the five active layers 18, namely, a first active layer 18a, a second active layer 18b, a third active layer 18c, a fourth active layer 18d, and a fifth active layer 18e, is sandwiched between respective enhanced layer pairs each consisting of one n-side enhanced layer 102 and one p-side enhanced layer 104. A barrier layer 108 is disposed between the p-side enhanced layer 104 disposed adjacently to the first active layer 18a, and the n-side enhanced layer 102 disposed adjacently to the second active layer 18b. Another barrier layer 108 is disposed between the p-side enhanced layer 104 disposed adjacently to the second active layer 18b, and the n-side enhanced layer 102 disposed adjacently to the third active layer 18c. Yet another barrier layer 108 is disposed between the p-side enhanced layer 104 disposed adjacently to the third active layer 18c, and the n-side enhanced layer 102 disposed adjacently to the fourth active layer 18d. A further barrier layer 108 is disposed between the p-side enhanced layer 104 disposed adjacently to the fourth active layer 18d, and the n-side enhanced layer 102 disposed adjacently to the fifth active layer 18e. Other structural aspects are the same for the semiconductor laser 100.

In this variation, the n-type cladding layer 14 and the p-type cladding layer 22 are formed of n-InP and p-InP, respectively, and have a thickness of 0.75 μm.

The n-side guide layer 16 and the p-side guide layer 20 are formed of i-In_{0.92}Ga_{0.08}As_{0.175}P_{0.825} and have a thickness of 140 nm.

The n-side enhanced layers 102 and p-side enhanced layers 104 located adjacently to the respective active layers are 4 nm thick and formed of i-In_{0.75}Ga_{0.25}As_{0.60}P_{0.40}.

The first active layer 18a, the second active layer 18b, reference to the semiconductor laser described in M. T. C. Silva, J. P. Sih, T. M. Chuo, J. K. Kirk, G. A. Evans, and J. K. Butler, “1.3 μm strained MQW AlGaInAs and InGaAsP ridge-waveguide lasers—A comparative study,n Microwave and Optoelectronics Conference, 1999 SBMO/IEEE MTT-S, APS and LEOS-IMOC '99, International Vol. 1, 9-12, August 1999, pp. 10-12.

Twenty-Eighth Variation

Semiconductor laser 142 of this variation is of a double-quantum-well (DQW) structure with two active layers. In the DQW structure, a first active layer 18a and a second active layer 18b are each disposed between respective enhanced layer pairs each consisting of one n-side enhanced layer 102 and one p-side enhanced layer 104. A barrier layer 108 is disposed between the p-side enhanced layer 104 disposed adjacently to the first active layer 18a, and the n-side enhanced layer 102 disposed adjacently to the second active layer 18b. Other structural aspects are the same for the semiconductor laser 100. A sectional view of the semiconductor laser 142, and a schematic diagram showing a conduction band structure of this laser are the same as those shown in FIGS. 39 and 40, respectively.

In this variation, an n-type cladding layer 14 and a p-type cladding layer 22 are formed of n-In_{0.49}Ga_{0.51}P and p-In_{0.49}Ga_{0.51}P, respectively, and have a thickness of 1.5 μm.

An n-side guide layer 16 and a p-side guide layer 20 are formed of i-GaAs and have a thickness of 20 nm.

The n-side enhanced layers 102 and p-side enhanced layers 104 disposed adjacently to the active layers 18a and 18b are each 3 nm thick and formed of i-In_{0.15}Ga_{0.85}As.

The first active layer 18a and the second active layer 18b are both 7 nm thick and formed of i-Ga_{0.67}In_{0.33}N_{0.006}As_{0.994}. The n-side enhanced layers 102 and the p-side enhanced layers 104 are thinner than the active layers 18a and 18b that are adjacent to the enhanced layers 102 and 104.

The barrier layer 108 is 13 nm thick and formed of the same i-GaAs constituent material as used for the n-side guide layer 16 and the p-side guide layer 20.

As shown in FIG. 40, the n-side enhanced layers 102 and the p-side enhanced layers 104 are constructed of a material whose bandgap energy level is somewhere in between a bandgap energy level of the adjacent first active layer 18a or second active layer 18b and a bandgap energy level of the adjacent n-side guide layer 16 or p-side guide layer 20 or of the barrier layer 108.

The semiconductor laser 142 of this variation also has advantageous effects equivalent to those of the foregoing semiconductor laser 100.

The enhanced layers in this variation are disposed with reference to the semiconductor laser described in S. Sato and S. Satoh, “Room-temperature continuous-wave operation of 1.24-μm GaInNAs lasers grown by metal-organic chemical vapor deposition,” IEEE J. Sel. Topics Quantum Electron., Vol. 5, No. 3, pp. 707-710, 1999.

Twenty-Ninth Variation

Semiconductor laser 144 of this variation is of a quintuple-quantum-well structure with five active layers, and has an emission wavelength of 1,550 nm. A sectional view of the semiconductor laser 144, and a schematic diagram showing a conduction band structure of this laser are the same as those shown in FIGS. 51 and 52, respectively.

The semiconductor laser 144 has an n-type cladding layer 14 and an n-side guide layer disposed in that order on an n-InP semiconductor'substrate 138. Also, a p-side guide layer 20 and a p-type cladding layer 22 are disposed in that order via five active layers 18, and a p-InP contact layer 24 is disposed on the third active layer 18c, the fourth active layer 18d, and the fifth active layer 18e are each 8 nm thick and formed of i-In_{0.775}Ga_{0.225}As_{0.71}P_{0.29}. The n-side enhanced layers 102 and the p-side enhanced layers 104 are each thinner than the active layer 18a, 18b, 18c, 18d, or 18e that is adjacent to the enhanced layer.

The barrier layers 108 are 20 nm thick and formed of i-In_{0.92}Ga_{0.08}As_{0.175}P_{0.825}, the same constituent material as used for the n-side guide layer 16 and the p-side guide layer 20.

As shown in FIG. 52, the n-side enhanced layers 102 and the p-side enhanced layers 104 are constructed of a material whose bandgap energy level is somewhere in between a bandgap energy level of the adjacent first active layer 18a, second active layer 18b, third active layer 18c, fourth active layer 18d, or fifth active layer 18e, and a bandgap energy level of the adjacent n-side guide layer 16, p-side guide layer 20, or barrier layer 108.

The semiconductor laser 144 of this variation also has advantageous effects equivalent to those of the foregoing semiconductor laser 100.

The enhanced layers in this variation are disposed with reference to the semiconductor laser described in S. C. Woodworth, D. T. Cassidy, and M. J. Hamp, “Experimental analysis of a broadly turnable InGaAsP laser with compositionally varied quantum wells,” IEEE J. Quantum Electron., Vol. 39, No. 3, pp. 426-430, 2003.

In the semiconductor laser of the present embodiment, enhanced layers thinner than an active layer and constructed of a material whose bandgap energy level is somewhere in between bandgap energy levels of the active layer and a guide layer, and whose refractive index is somewhere in between refractive indices of the active layer and the guide layer, are provided adjacently to the active layer. This configuration makes it possible for the semiconductor laser to be reduced in threshold carrier density and even in threshold current. Also, this configuration reduces not only quasi-Fermi levels of a conduction band or a valence band, but also an operating voltage, and preventing an overflow of carriers, thus improving high-temperature characteristics of the semiconductor laser.

While the above description of the present embodiment has covered structures up to a quintuple-quantum-well structure, equivalent effects can also be yielded in structures having an even larger number of quantum well layers.

Also, while examples of typical semiconductor laser structures for each emission wavelength, provided with enhanced layers, have been shown in the description of the present embodiment, these examples do not limit the scope of the invention and equivalent effects can be obtained in other semiconductor laser structures as well if the relationships of refractive indices and of bandgap energy levels are satisfied.

In addition, while examples of undoped layers, except for the substrate, the cladding layers, and the contact layer, have been shown, equivalent effects can likewise be obtained by doping the guide layers, the barrier layers, and other layers.

Furthermore, while the present embodiment has been described taking as an example of a general semiconductor laser in which the effective mass of electrons is smaller than that of holes, equivalent effects similar to the above example can be obtained in an example of the semiconductor laser in which the effective mass of holes is smaller than that of electrons by introducing a strained active layer.

As described above, the semiconductor laser device according to the present embodiment comprises: a first electroconductive type of semiconductor substrate; a first electroconductive type of first cladding layer disposed on the semiconductor substrate; a first optical waveguide layer disposed on the first cladding layer; an active layer of a quantum well structure, disposed on the first optical waveguide layer, the active layer being of a greater refractive index than the first optical waveguide layer; a second optical waveguide layer disposed on the active layer, the second optical waveguide layer being of a smaller refractive index than the active layer; a first semiconductor layer disposed in contact with the active layer between the second optical waveguide layer or the first optical waveguide layer and the active layer, the first semiconductor layer having a bandgap energy level which is somewhere in between a bandgap energy level of the active layer and a bandgap energy level of the adjacent second optical waveguide layer or first optical waveguide layer, and which is discretely different from the bandgap energy level of the active layer and the bandgap energy level of the adjacent second optical waveguide layer or first optical waveguide layer, having a refractive index which is somewhere in between a refractive index of the active layer and a refractive index of the adjacent second optical waveguide layer or first optical waveguide layer, and being smaller than the active layer in thickness; and a second electroconductive type of second cladding layer disposed on the second optical waveguide layer; wherein a zeroth-order quantum level is in a conduction band offset or valence band offset between the active layer and the second optical waveguide layer or the first optical waveguide layer. Accordingly, the semiconductor laser device is reduced in threshold carrier density and in a quasi-Fermi level of the conduction band or the valance band. Therefore, threshold current and operating voltage are reduced to suppress an overflow of carriers, and hence improves in high-temperature characteristics. These facts, in turn, mean that a semiconductor laser device of a low operating voltage and a small threshold current can be constructed.

As set forth above, the semiconductor laser device according to the present invention is suitable for use as a general-purpose semiconductor laser device, inclusive of a high-output power semiconductor laser device used as an pumping light source in an industrial laser.

While the presently preferred embodiments of the present invention have been shown and described. It is to be understood these disclosures are for the purpose of illustration and that various changes and modifications may be made without departing from the scope of the invention as set forth in the appended claims.

1. A semiconductor laser device comprising:
a first conductivity type GaAs substrate;
a first conductivity type first cladding layer of (Alₓ₁Ga₁₋ₓ₁)_{y1}In_{1-y1}P (1>x1>0, 0.52>y1>0.48), disposed on the GaAs substrate;
a first optical waveguide layer of undoped InᵤGa₁₋ᵤP (1>u>0) lattice-matched to GaAs, disposed on the first cladding layer;
an active layer disposed on the first optical waveguide layer, the active layer having a larger refractive index than the first optical waveguide layer and including a layer of InᵥGa₁₋ᵥAs (0.24>v>0) as a quantum-well layer;
a second optical waveguide layer of undoped InᵤGa₁₋ᵤP (1>u>0), disposed on the active layer, the second optical waveguide layer having a smaller refractive index than the active layer; and
a second conductivity type second cladding layer of (Alₓ₂Ga₁₋ₓ₂)_{y2}In_{1-y2}P (1>x2>0, 0.52>y2>0.48), disposed on the second optical waveguide layer.

2. The semiconductor laser device according to claim 1, wherein
the active layer includes one or a plurality of quantum well layers and
total layer thickness of the one or a plurality of quantum well layers is about 12 nm.

3. The semiconductor laser device according to claim 1, wherein
the first cladding layer and the second cladding layer both have an Al-content ratio of at least 0.1 and
the first optical waveguide layer and the second optical waveguide layer both have a layer thickness of at least 400 nm.

4. The semiconductor laser device according to claim 1, includes first barrier layers of undoped GaAs_{1-w}P_{w} (0.2>w>0) disposed between the active layer and the first optical waveguide layer and between the active layer and the second optical waveguide layer.

5. The semiconductor laser device according to claim 4, wherein second barrier layers of undoped GaAs disposed between the active layer and the first optical waveguide layer and between the active layer and the second optical waveguide layer.

6. The semiconductor laser device according to claim 5, wherein one of the second barrier layers is disposed between the active layer and the first barrier layer.

7. The semiconductor laser device according to claim 4, wherein
the first cladding layer and the second cladding layer both have an Al-content ratio of at least 0.1 and
the first optical waveguide layer and the second optical waveguide layer both have a layer thickness of at least 350 nm.

8. A semiconductor laser device comprising:
a first conductivity type semiconductor substrate;
a first conductivity type first cladding layer disposed on the semiconductor substrate;
a first optical waveguide layer disposed on the first cladding layer;
an active layer having a quantum well structure, disposed on the first optical waveguide layer, the active layer having a larger refractive index than the first optical waveguide layer;
a second optical waveguide layer disposed on the active layer, the second optical waveguide layer having a smaller refractive index than the active layer;
a first semiconductor layer disposed in contact with the active layer between the second optical waveguide layer or the first optical waveguide layer and the active layer, the first semiconductor layer having a bandgap energy level between bandgap energy level of the active layer and *bandgap energy level of the second optical waveguide layer or first optical waveguide layer, and which is different from the bandgap energy level of the active layer and the bandgap energy level of the second optical waveguide layer or first optical waveguide layer, having a refractive index between a refractive index of the active layer and a refractive index of the second optical waveguide layer or first optical waveguide layer, and smaller than the active layer in thickness; and
a second conductivity type second cladding layer disposed on the second optical waveguide layer, wherein a zeroth-order quantum level is in a conduction band offset or valence band offset between the active layer and the second optical waveguide layer or the first optical waveguide layer.

9. The semiconductor laser device according to claim 8, wherein a zeroth-order quantum level is in a conduction band offset or valence band offset between the active layer and the first semiconductor layer, and first-order and higher-order quantum levels are in a conduction band offset or valence band offset between the first semiconductor layer and the second optical waveguide layer or the first optical waveguide layer.

10. The semiconductor laser device according to claim 8, including first semiconductor layers disposed between the second optical waveguide layer and the active layer and between the first optical waveguide layer and the active layer, respectively.

11. The semiconductor laser device according to claim 8, wherein the active layer is disposed in a plurality places via a barrier layer which has the same bandgap energy and refractive index as the second optical waveguide layer or the first optical waveguide layer.
